(19) United States
(12) Patent Application Publication
(10) Pub. No.: US 2026/0369522 A1
(43) Pub. Date: Nov. 19, 2026

(54) SUBSTRATE ETCHING APPARATUS

(71) Applicant: SAMSUNG ELECTRONICS CO., LTD., Suwon-si (KR)

(72) Inventors: Janghyeon LYU, Suwon-si (KR); Donghoon KWON, Suwon-si (KR); llyoung YOON, Suwon-si (KR); Jinoh IM, Suwon-si (KR)

(73) Assignee: SAMSUNG ELECTRONICS CO., LTD., Suwon-si (KR)

(21) Appl. No.: 19/542,082

(22) Filed: Feb. 17, 2026

(30) Foreign Application Priority Data
May 15, 2025 (KR) 10-2025-0063519

(51) Int. Cl. H01J 37/305; G02B 19/00; H01J 37/22; H01J 37/30; H10P 72/00

(52) U.S. Cl. CPC H01J 37/3053; G02B 19/0009; G02B 19/0047; H01J 37/22; H01J 37/3002; H10P 72/0421

(57) ABSTRACT

A substrate etching apparatus includes a plasma jet device configured to eject a plasma jet toward an etching region, the etching region including a portion of an entire region of a top surface of a target, and an optical heating module configured to radiate a laser beam to the etching region, wherein the optical heating module includes a laser light source configured to output the laser beam, a focusing lens configured to focus the laser beam onto a beam spot on the top surface of the target, and a scanning mirror between the laser light source and the focusing lens along an optical path of the laser beam, and the scanning mirror is configured to move the beam spot along a scanning path within the etching region.

### CROSS-REFERENCE TO RELATED APPLICATION

This application is based on and claims priority under 35 U.S.C. §119 to Korean Patent Application No. 10-2025-0063519, filed on May. 15, 2025, in the Korean Intellectual Property Office, the disclosure of which is incorporated by reference herein in its entirety.

### BACKGROUND

The present disclosure relates to a substrate etching apparatus and a substrate etching method, and more specifically, to a substrate etching apparatus and a substrate etching method that etch a target by using a plasma jet.

To planarize a surface of the wafer, a grinding and polishing process may be performed on a wafer. However, after the grinding and polishing process is performed, a plurality of protrusions may remain on the surface of the wafer. Due to the remaining protrusions, the surface of the wafer may be uneven, and the overall thickness of the wafer may not be uniform.

The non-uniform thickness of the wafer may negatively affect a subsequent semiconductor manufacturing process. Accordingly, there is a growing need for a method of removing the remaining protrusions on the surface of the wafer to ensure an overall uniform thickness of the wafer.

### SUMMARY

One or more embodiments of the present disclosure may provide a substrate etching apparatus that may precisely remove protrusions and recesses from a surface of a target.

One or more embodiments of the present disclosure may provide a substrate etching apparatus that may have improved throughput and improved spatial resolution.

The present disclosure is not limited to any particular embodiment(s) detailed herein, and those skilled in the art will readily understand that other embodiments, applications, and/or objectives are within the scope of the present disclosure.

According to one or more embodiments of the disclosure, there is provided a substrate etching apparatus including: a plasma jet device configured to eject a plasma jet toward an etching region, the etching region including a portion of a top surface of a target; and an optical heating module configured to radiate a laser beam to the etching region, the optical heating module including: a laser light source configured to output the laser beam; a focusing lens configured to focus the laser beam onto a beam spot on the top surface of the target; and a scanning mirror between the laser light source and the focusing lens along an optical path of the laser beam, and configured to move the beam spot along a scanning path within the etching region.

According to one or more embodiments of the disclosure, there is provided a substrate etching apparatus including: a plasma jet device configured to eject a plasma jet toward a top surface of a target; a laser light source configured to output a laser beam; a focusing lens configured to focus the laser beam onto a beam spot on a portion of the top surface of the target; a scanning mirror between the laser light source and the focusing lens along an optical path of the laser beam; a stage configured to support the target and drive the target in a horizontal direction; and a controller configured to control the stage and the scanning mirror, wherein the controller is configured to identify an etching region on the top surface of the target based on information about the stage driving the target, and control the scanning mirror to move the beam spot along a scanning path within the etching region.

According to one or more embodiments of the disclosure, there is provided a substrate etching apparatus including: a stage configured to support a target and drive the target in a horizontal direction; a plasma jet device including a plurality of jet nozzles respectively configured to eject plasma jets toward an etching region of the target; and a plurality of optical heating modules respectively configured to output a plurality of laser beams respectively corresponding to a plurality of sub-etching regions in the etching region, wherein each of the plurality of optical heating modules include: a laser light source configured to output a laser beam of the plurality of laser beams; a focusing lens configured to focus the laser beam onto a beam spot on a top surface of the target; and a scanning mirror between the laser light source and the focusing lens along an optical path of the laser beam, and wherein the scanning mirrors of the plurality of optical heating modules are respectively configured to move the beam spots along a plurality of scanning paths respectively corresponding to the plurality of sub-etching regions.

### BRIEF DESCRIPTION OF DRAWINGS

Embodiments will be more clearly understood from the following detailed description taken in conjunction with the accompanying drawings in which:

FIG. 1 is a cross-sectional view of a substrate etching apparatus according to one or more embodiments;

FIG. 2 is a flowchart for describing a substrate etching method for a substrate etching apparatus, according to one or more embodiments;

FIG. 3 is a perspective view of a substrate etching apparatus according to one or more embodiments;

FIG. 4 is a cross-sectional view of a target according to one or more embodiments;

FIG. 5 is a plan view illustrating a method of scanning an etching region with a beam spot, according to one or more embodiments;

FIG. 6 is a plan view illustrating an independent scanning path within an etching region, according to one or more embodiments;

FIG. 7 is a plan view illustrating an overlapped scanning path within an etching region, according to one or more embodiments;

FIG. 8 is a graph illustrating one or more aspects of a method of outputting a laser beam from a laser light source, according to one or more embodiments;

FIG. 9 is a conceptual diagram illustrating a method of determining the size of a beam spot, according to one or more embodiments;

FIG. 10 is a perspective view of a plasma jet device according to one or more embodiments;

FIG. 11 is a plan view illustrating an etching profile of a plasma jet device according to one or more embodiments;

FIG. 12 is a plan view illustrating an etching profile of a plasma jet device according to one or more embodiments;

FIG. 13 is a perspective view of a plasma jet device according to one or more embodiments;

FIG. 14 is a plan view illustrating an etching profile of a plasma jet device according to one or more embodiments;

FIG. 15 is a plan view illustrating an etching profile of a plasma jet device according to one or more embodiments;

FIG. 16 is a perspective view of a substrate etching apparatus according to one or more embodiments; and

FIG. 17 is a plan view illustrating an optical heating method for a substrate etching apparatus, according to one or more embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present.

As used herein, the term “and/or” includes any and all combinations of one or more of the associated listed items. As used herein, expressions such as “at least one of,” when preceding a list of elements, modify the entire list of elements and do not modify the individual elements of the list. For example, the expression, “at least one of a, b and c,” and “at least one of a, b, or c” should be understood as including only a, only b, only c, both a and b, both a and c, both b and c, or all of a, b and c.

It will be also understood that, even if a certain step or operation of manufacturing an apparatus or structure is described later than another step or operation, the step or operation may be performed later than the other step or operation unless the other step or operation is described as being performed after the step or operation.

Various embodiments of the present document and terms used therein are not intended to limit the technical features described in this document to specific embodiments, and should be understood to include various modifications, equivalents, or substitutes of the corresponding embodiments.

In connection with the description of the drawings, similar reference numerals may be used for similar or related components.

The singular form of a noun corresponding to an item may include one or a plurality of the items unless clearly indicated otherwise in a related context.

In addition, the terms “portion”, “part”, “unit”, “module” or “member” may be implemented in hardware or software. Depending on the embodiments, a plurality of “portions”, “parts”, “units”, “modules” or “members” may be implemented as a single element, or a single “portion”, “part”, “unit”, “module” or “member” may include a plurality of elements.

It will be understood that, although the terms “first”, “second”, “third”, “primary”, “secondary”, “tertiary”, etc., may be used herein to describe various elements, but elements are not limited by these terms. These terms are only used to distinguish one element from another element. For example, without departing from the scope of the disclosure, a first element may be termed as a second element, and a second element may be termed as a first element. The term of “and/or” includes a plurality of combinations of relevant items or any one item among a plurality of relevant items.

When an element (e.g., a first element) is referred to as being “(functionally or communicatively) coupled” or “connected” to another element (e.g., a second element), the first element may be connected to the second element, directly (e.g., wired), wirelessly, or through a third element.

In this disclosure, the terms “containing”, “including”, “comprising”, “having”, and the like are used to specify features, numbers, steps, operations, elements, components, or combinations thereof, but do not preclude the presence or addition of one or more of the features, numbers, steps, operations, elements, components, or combinations thereof.

In addition, in the present disclosure, the meaning of “identical” includes cases where properties are similar to each other or similar within a certain range. Furthermore, unless clearly indicated, stated, and/or shown otherwise; as used herein the terms “identical”, “uniform”, “equal”, and/or “the same” mean “substantially identical”, “substantially uniform”, “substantially equal”, and/or “substantially the same”. The meaning of substantially identical should be understood to include numerical values within manufacturing error ranges, machining or processing tolerances, and/or differences within a range that is so insignificant such that neither the structure nor function of the embodiments disclosed herein are materially altered, inhibited, or destroyed.

As used herein, the terms “front (or forward)”, “rear (or back, rearward)”, “left”, “right”, “up (or top)”, “down (or bottom)” and the like may be defined with reference to the drawings, and may not be intended to limit the shape and position of each component.

Herein, a horizontal direction may include a first horizontal direction (X direction) and a second horizontal direction (Y direction) that cross each other. A direction crossing the first horizontal direction (X direction) and the second horizontal direction (Y direction) may be referred to as a vertical direction (Z direction). Herein, a vertical level may be referred to as a height level of any component in the vertical direction (Z direction).

Hereinafter, embodiments of the present disclosure will be described clearly and in detail so that those skilled in the art can carry out the present disclosure.

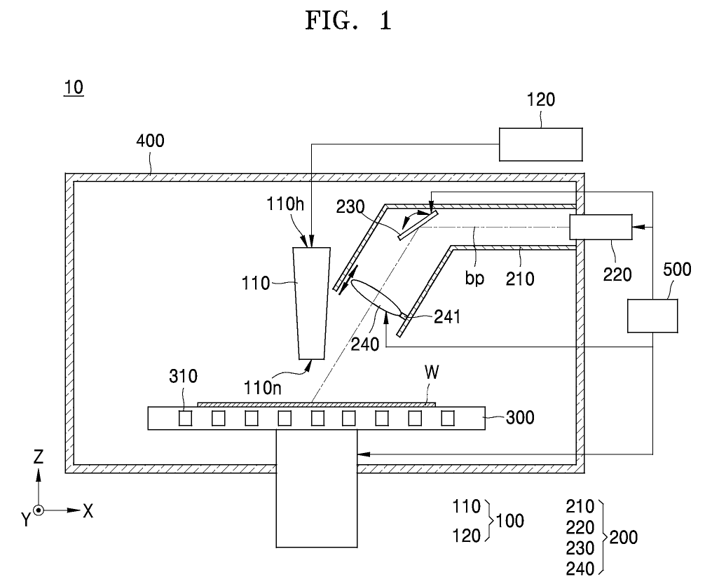

FIG. 1 is a cross-sectional view of a substrate etching apparatus 10 according to one or more embodiments.

The substrate etching apparatus 10 may include a plasma jet device 100, an optical heating module 200, a stage 300, a chamber housing 400, and a controller 500.

The plasma jet device 100 may include a jet housing 110 and a gas source 120. The plasma jet device 100 may eject a plasma jet toward a top surface of a target W. In the present disclosure, the plasma jet may refer to plasma ejected toward a partial region of the entire region of the top surface of the target W. The plasma jet may include plasma particles such as ion particles, radical particles, and electrons.

The jet housing 110 may form an exterior of the plasma jet device 100. A plasma generation device may be arranged within the jet housing 110. The plasma generation device may be implemented as various types of plasma sources. For example, the plasma generation device may be implemented as a direct current (DC) plasma source, a radio frequency (RF) plasma source, a dielectric barrier discharge (DBD) plasma source, and/or a microwave plasma source, or may be various types of devices configured to generate plasma by receiving and discharging a gas.

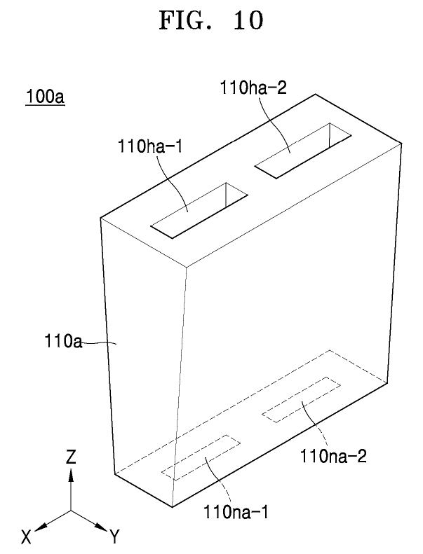

The jet housing 110 may include a gas inlet 110h arranged in a top surface of the jet housing 110 and a jet nozzle 110n arranged in a bottom surface of the jet housing 110. The gas inlet 110h may be a hole that receives gas supplied from the gas source 120 and introduces the gas into the plasma generation device arranged inside the jet housing 110. The jet nozzle 110n may be a hole that discharges the plasma particles generated by the plasma generation device, toward the top surface of the target W. In one or more one or more embodiments, the number of gas inlets 110h and the number of jet nozzles 110n may correspond to each other. For example, when one gas inlet 110h is arranged in the top surface of the jet housing 110, one jet nozzle 110n may be arranged in the bottom surface of the jet housing 110. In one or more embodiments, a position of the gas inlet 110h may correspond to a position of the jet nozzle 110n. For example, the jet nozzle 110n may be arranged to overlap the gas inlet 110h in the vertical direction, and a center point of the jet nozzle 110n may be arranged at the same horizontal coordinate as a center point of the gas inlet 110h. In one or more embodiments, the jet housing 110 may include a plurality of gas inlets 110h and a plurality of jet nozzles 110n. One or more embodiments in which the jet housing 110 includes a plurality of gas inlets 110h and a plurality of jet nozzles 110n will be described in detail with reference to FIGS. 10 to 15.

The gas source 120 may supply an etching gas to the gas inlet 110h of the jet housing 110. The etching gas may be implemented as various types of gases. The etching gas may be supplied to the plasma generation device arranged inside the jet housing 110, and the plasma generation device may discharge the etching gas. Plasma containing various types of plasma particles may be generated by the discharge of the etching gas. For example, the etching gas may be sulfur hexafluoride (SF₆) gas, and plasma containing various types of ion particles (for example, SF₅ ⁺, SF₄ ⁺, etc.) and various types of radical particles (for example, F•, SF₄•, etc.) may be generated by the discharge of the sulfur hexafluoride (SF₆) gas.

The optical heating module 200 may include a housing 210, a laser light source 220, a scanning mirror 230, and a focusing lens 240. The optical heating module 200 may heat a portion of the entire region of the top surface of the target W, based on radiation of a laser beam.

The housing 210 may form an overall exterior of the optical heating module 200. The laser light source 220, the scanning mirror 230, and the focusing lens 240 may be arranged inside the housing 210. The housing 210 may protect the laser light source 220, the scanning mirror 230, and the focusing lens 240 from external contamination and impact. In addition, the housing 210 may protect the laser light source 220, the scanning mirror 230, and the focusing lens 240 from high-temperature plasma. FIG. 1 shows that the housing 210 protrudes from an inner wall of the chamber housing 400 toward the inside of the chamber housing 400, but this is merely an example, and the housing 210 may protrude from a top surface of the chamber housing 400 or may be arranged at various positions.

The laser light source 220 may output a laser beam toward the scanning mirror 230. The laser beam output from the laser light source 220 may be light that includes at least one of ultraviolet (UV), extreme ultraviolet (EUV), X-rays, visible light, and infrared (IR).

The scanning mirror 230 may be arranged between the laser light source 220 and the focusing lens 240 along an optical path bp of the laser beam. The scanning mirror 230 may reflect the laser beam incident on the scanning mirror 230 and direct the laser beam to the focusing lens 240. The scanning mirror 230 may include a rotary actuator. Accordingly, the scanning mirror 230 may be rotationally driven, and a region of the top surface of the target W, onto which the laser beam is radiated, may be changed based on the rotational driving of the scanning mirror 230. FIG. 1 shows that the scanning mirror 230 may include only one mirror, but in one or more embodiments, the scanning mirror 230 may include a plurality of mirrors. In one or more embodiments, the scanning mirror 230 may be implemented as a galvanometer scanner device.

The focusing lens 240 may focus the laser beam onto a beam spot on the top surface of the target W. In this regard, the beam spot may refer to a region within the entire region of the top surface of the target W, where heating by the laser beam is performed. FIG. 1 shows that the focusing lens 240 includes only one lens, but in one or more embodiments, the focusing lens 240 may include a plurality of lenses arranged along the optical path bp of the laser beam.

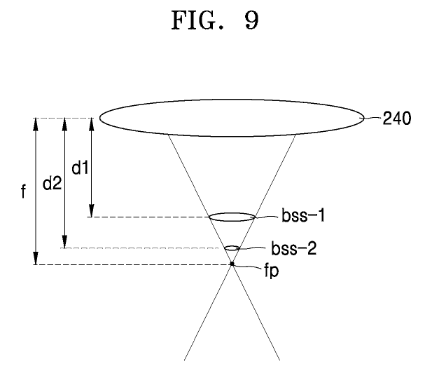

The focusing lens 240 may be connected to a lens driving device that drives the focusing lens 240 in a direction parallel to the optical path bp of the laser beam. The lens driving device may be fixed to the housing 210 or the chamber housing 400. The lens driving device may include a linear actuator, a linear guide, and/or a slider structure. The lens driving device may change (i.e., adjust, modify, optimize, recalibrate, and/or otherwise alter) a position of the focusing lens 240 in a direction parallel to the optical path bp of the laser beam. As the position of the focusing lens 240 is changed, a distance between the focusing lens 240 and the target W may vary in size and/or orientation, and the size of the beam spot may vary. Accordingly, because the lens driving device may be configured to adjust a position of the focusing lens 240, and because adjusting the position of the focusing lens may, as a result, adjust both a distance between the focusing lens 240 and the target W, as well as a size of the beam spot, the lens driving device may also be configured to adjust: a distance between the focusing lens 240 and the target W, and/or a size of the beam spot of the laser beam La. That is, the lens driving device may be configured to adjust a size of the beam spot by adjusting a position of the focusing lens in a direction parallel to the optical path of the laser beam. A method of changing the size of a beam spot will be described in detail with reference to FIG. 9.

On the top surface of the target W, the beam spot may move according to the rotational driving of the scanning mirror 230. For example, when the scanning mirror 230 is rotated by a first angle in a first rotational direction, the beam spot may be located in a first region of the target W, and when the scanning mirror 230 is rotated by a second angle in the first rotational direction, the beam spot may be located in a second region of the target W.

The stage 300 may support the target W. The target W may be fixed to a top surface of the stage 300. That is, the stage 300 may be configured to support the target W and to secure the target W thereto. The stage 300 may be arranged in a lower portion of the chamber housing 400. The stage 300 may drive the target W in the horizontal direction. While the plasma jet device 100 is fixed at a specific position, the target W is driven in the horizontal direction by the stage 300, and thus, an etching region may sequentially move along a predetermined path within the entire region of the top surface of the target W. In this regard, the etching region may refer to a region within the entire region of the top surface of the target W, toward which a plasma jet is ejected at a specific time point. For example, the plasma jet device 100 may eject a plasma jet onto the first region of the top surface of the target W at a first time point, and may eject a plasma jet onto the second region of the top surface of the target W at a second time point. In this case, a first etching region corresponding to the first time point may be the first region, and a second etching region corresponding to the second time point may be the second region.

The stage 300 may include a cooling path 310. The cooling path 310 may be arranged inside the stage 300 and may be configured to lower the temperature of the target W. A refrigerant may be supplied to the cooling path 310. Cooling of the target W by the cooling path 310 may prevent an unintended temperature rise. For example, when optical heating is performed on the etching region by the optical heating module 200, heat may be conducted to the remaining region other than the etching region of the entire region of the top surface of the target W, and thus, an unintended temperature rise may occur in the remaining region. The cooling of the target W by the cooling path 310 may cause a large temperature difference between the etching region and the remaining region, thereby suppressing an unintended temperature rise.

The chamber housing 400 may limit a space in which an etching process is performed and may seal the space from the outside (i.e., ambient and/or external environment outside of the chamber housing 400). An internal space of the chamber housing 400 may be maintained in a vacuum state, and a shape of the chamber housing 400 may be cylindrical, spherical, hemispherical, cubic, or any other suitable shape. The chamber housing 400 may be formed of a metal material, and may include an insulating material such as ceramic or quartz.

The controller 500 may be connected to the laser light source 220, the scanning mirror 230, the focusing lens 240, and the stage 300, and may control overall operations of the substrate etching apparatus 10. The controller 500 may be implemented as hardware, firmware, software, or any combination thereof. For example, the controller 500 may include a computing device such as a workstation computer, a desktop computer, a laptop computer, or a tablet computer. The controller 500 may include a complex processor such as a microprocessor, a central processing unit (CPU), or a graphics processing unit (GPU), at least one processor implemented by software, dedicated hardware, or firmware. The controller 500 may be implemented by, for example, a general-purpose computer or an application-specific hardware such as a digital signal processor (DSP), a field programmable gate array (FPGA), and an application-specific integrated circuit (ASIC).

The substrate etching apparatus 10 according to one or more embodiments may perform an etching process with a high etch rate on a region of the target W, which is heated to a relatively high temperature, and perform an etching process with a low etch rate on a region of the target W, which is heated to a relatively low temperature, based on optical heating of the target W. Accordingly, the substrate etching apparatus 10 may improve a spatial resolution of an etching process. In this regard, the spatial resolution of an etching process refers to the minimum unit area to which different etching conditions may be applied. For example, when a spatial resolution of an etching process of the substrate etching apparatus 10 is significantly improved, the substrate etching apparatus 10 may apply different etching conditions to area units ranging from several square nanometers (nm²) to several tens of square nanometers (nm²). In contrast, when a spatial resolution of the etching process of the substrate etching apparatus 10 is poor (i.e., the minimum unit area to which different etching conditions may be applied is relatively large and/or wide), the substrate etching apparatus 10 may apply different etching conditions at area units ranging from several square millimeters (mm²) to several hundreds of square millimeters (mm²).

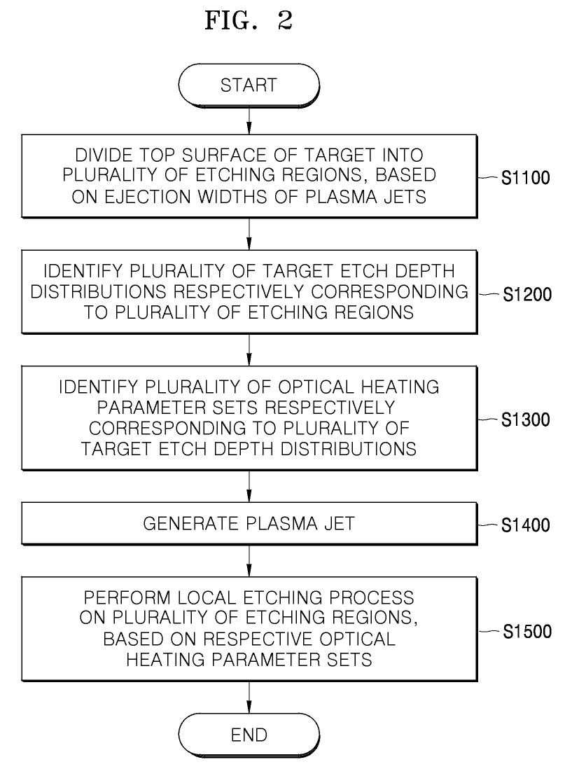

The overall operations of the substrate etching apparatus 10 controlled by the controller 500 will be described in detail with reference to FIGS. 2 to 9.

FIG. 2 is a flowchart for describing a substrate etching method S1000 for the substrate etching apparatus 10, according to one or more embodiments.

Referring to FIG. 2, in operation S1100, the substrate etching apparatus 10 may divide the top surface of the target W into a plurality of etching regions, based on ejection widths of plasma jets. For example, among the plurality of etching regions, the first etching region may be a region toward which a plasma jet is ejected at the first time point, and the second etching region may be a region toward which a plasma jet is ejected at the second time point.

In one or more embodiments, the target W may be a wafer, and a region of a plasma jet ejected from the plasma jet device 100 onto a top surface of the wafer may be a rectangular region. In this case, the top surface of the wafer may be divided into a plurality of rectangular regions, and the plurality of rectangular regions may respectively be identified as a plurality of etching regions. According to one or more embodiments, the plurality of etching regions may comprise mutually distinct independent regions that do not overlap each other in plan view (i.e., top-down, or “layout” view). According to one or more embodiments, the plurality of etching regions may partially overlap each other in a plan view.

Next, in operation S1200, the substrate etching apparatus 10 may identify a plurality of target etch depth distributions respectively corresponding to the plurality of etching regions.

The plurality of target etch depth distributions respectively corresponding to the plurality of etching regions may be substantially identical to each other in size and/or shape, or may be different from each other in size and/or shape. For example, a first target etch depth distribution corresponding to the first etching region may have a uniform value across the entire first etching region, whereas a second target etch depth distribution corresponding to the second etching region may have irregular target etch depths across the entire second etching region. In this regard, a target etch depth distribution may include a distribution of a plurality of target etch depths respectively corresponding to a plurality of points (or a plurality of unit etching regions) included in a specific etching region.

Next, in operation S1300, the substrate etching apparatus 10 may identify a plurality of optical heating parameter sets respectively corresponding to the plurality of target etch depth distributions.

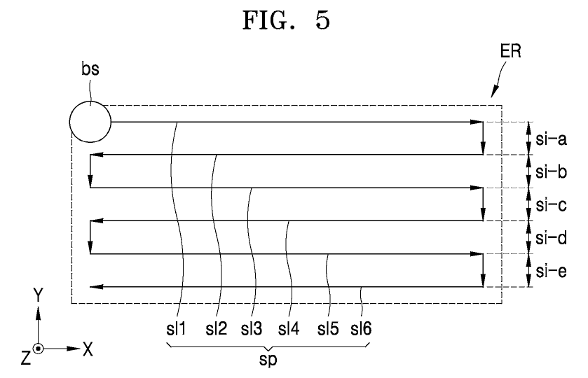

In this regard, an optical heating parameter set may include at least one of the size of a beam spot, a scanning interval, a scanning speed profile, and a pulse interval profile, each corresponding to a specific target etch depth distribution. For example, the optical heating parameter set may include the size of the beam spot and the scanning interval. In this case, the substrate etching apparatus 10 may identify only the sizes of a plurality of beam spots and a plurality of scanning intervals, each respectively corresponding to the plurality of target etch depth distributions As another example, the optical heating parameter set may include the size of the beam spot and the scanning speed profile, and in this case, the substrate etching apparatus 10 may identify the sizes of a plurality of beam spots and a plurality of scanning speed profiles, each respectively corresponding to the plurality of target etch depth distributions. A method of identifying the optical heating parameter sets respectively corresponding to the plurality of target etch depth distributions will be described in detail with reference to FIGS. 5 to 9.

Next, in operation S1400, the substrate etching apparatus 10 may generate a plasma jet.

In one or more embodiments, the plasma jet device 100 may generate a plasma jet and eject the plasma jet toward an etching region on the top surface of the target W. To eject a plasma jet having a specific density distribution and a specific shape, the substrate etching apparatus 10 may adjust a flow rate of an etching gas supplied to the gas inlet 110h.

Next, in operation S1500, the substrate etching apparatus 10 may perform a local etching process on the plurality of etching regions, based on the respective optical heating parameter sets. In this regard, the local etching process may refer to a process in which plasma jets are respectively ejected onto the plurality of etching regions through the plasma jet device 100, and simultaneously, optical heating corresponding to the plurality of optical heating parameter sets is respectively performed on the plurality of etching regions through the optical heating module 200. As described above with reference to FIG. 1, because the target W is driven in the horizontal direction by the stage 300, the ejection of the plasma jets by the plasma jet device 100 and the optical heating by the optical heating module 200 may be sequentially performed over the entire region of the top surface of the target W.

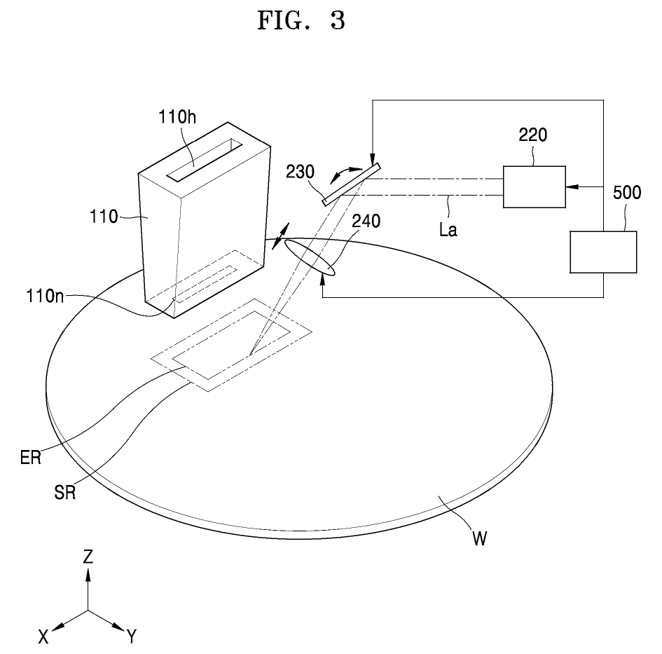

FIGS. 3 to 9 illustrate one or more embodiments of a method of optically heating a single etching region using the optical heating module 200.

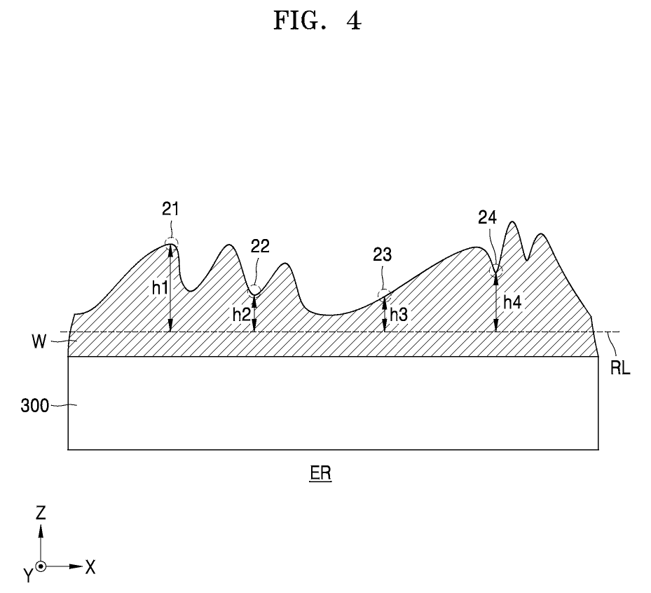

FIG. 3 is a perspective view of the substrate etching apparatus 10 according to one or more embodiments. FIG. 4 is a cross-sectional view of the target W according to one or more embodiments.

Referring to FIG. 3, the jet nozzle 110n may eject a plasma jet toward an etching region ER, and the scanning mirror 230 may move a beam spot of a laser beam La along a scanning path within the etching region ER.

In one or more embodiments, the substrate etching apparatus 10 may include one gas inlet 110h arranged in the top surface of the jet housing 110 and one jet nozzle 110n arranged in the bottom surface of the jet housing 110. In this regard, the gas inlet 110h and the jet nozzle 110n may be arranged at positions corresponding to each other and may be implemented in the form of rectangular slits. Because the gas inlet 110h and the jet nozzle 110n have rectangular slit shapes, the etching region ER may also have a rectangular shape. In this regard, a plasma density of the plasma jet may be substantially uniform across the entire region of the etching region ER.

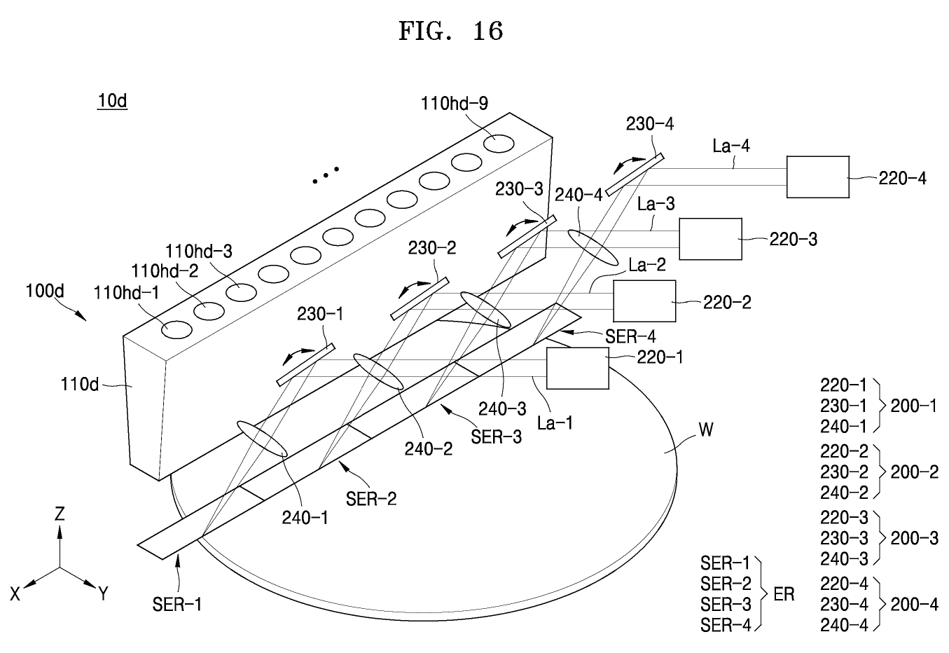

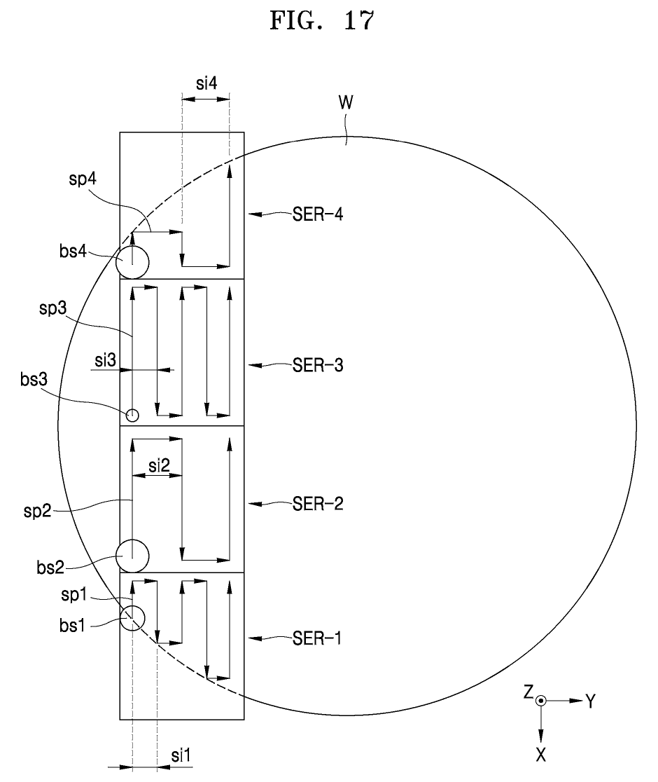

In one or more embodiments, a scannable region SR may be larger than the etching region ER. In this regard, the scannable region SR refers to a range of positions on the top surface of the target W where the beam spot of the laser beam La may move due to rotational driving of the scanning mirror 230. In one or more embodiments, the etching region ER may be substantially identical to the scannable region SR. In addition, the etching region ER may be larger than the scannable region SR, and in this case, a plurality of optical heating modules 200 may be provided. One or more embodiments in which the plurality of optical heating modules 200 are provided will be described in detail with reference to FIGS. 16 and 17.

In one or more embodiments, the controller 500 may identify an etching region based on information associated with the operability of the stage 300 to drive (i.e., move, reposition, relocate, reorient, affix, attach, and/or remove) the target W. The controller 500 may control the scanning mirror 230 such that the beam spot of the laser beam La moves along the scanning path within the etching region ER. The scanning mirror 230 may be rotationally driven according to a control signal from the controller 500, and the beam spot may be moved along the scanning path by the rotational driving of the scanning mirror 230. The controller 500 may control the scanning of the etching region ER with the beam spot based on the size of a beam spot corresponding to a target etch depth distribution of the etching region ER, a scanning interval, a scanning speed profile, or a pulse interval profile. In detail, the control related to the scanning interval and the scanning speed profile may be performed based on a control operation of the controller 500 for the scanning mirror 230. In addition, the control related to the beam spot size may be performed based on driving of the focusing lens 240 by the controller 500, and the control related to the pulse interval profile may be performed based on a control operation of the controller 500 for the laser light source 220.

Referring to FIG. 4, the etching region ER may include a plurality of points (for example, first to fourth points 21, 22, 23, and 24). A plurality of target etch depths respectively corresponding to the plurality of points may be different from each other. For example, a first target etch depth corresponding to the first point 21 may be a first thickness h1, a second target etch depth corresponding to the second point 22 may be a second thickness h2, a third target etch depth corresponding to the third point 23 may be a third thickness h3, and a fourth target etch depth corresponding to the fourth point 24 may be a fourth thickness h4. In this regard, the plurality of target etch depths may be determined according to the degrees of protrusion of the plurality of points from a reference level RL, respectively. The reference level RL may be a target etch level of the target W. As shown in FIG. 4, the thicknesses may gradually decrease in the order of the first thickness h1, the fourth thickness h4, the second thickness h2, and the third thickness h3. The greater the target etch depth for a specific point, the greater the required etch depth for the specific point, and thus, optical heating for the first point 21 is required to be the strongest, and the intensity of optical heating is required to decrease in the order of the fourth point 24, the second point 22, and the third point 23.

In one or more embodiments, to respectively set different intensities of optical heating for the plurality of points within the etching region ER, the controller 500 may identify a scanning speed profile corresponding to a target etch depth distribution of the etching region ER. In this case, the controller 500 may determine a scanning speed of the beam spot for the first point 21 to be the slowest, and may determine a scanning speed profile such that the scanning speed of the beam spot gradually increases in the order of the fourth point 24, the second point 22, and the third point 23.

In one or more embodiments, the controller 500 may identify a pulse interval profile corresponding to a target etch depth distribution of the etching region ER. In this case, the controller 500 may determine a pulse interval of the laser beam La for the first point 21 to be the shortest, and may determine a pulse interval profile such that the pulse interval of the laser beam La gradually increases in the order of the fourth point 24, the second point 22, and the third point 23.

As described above, the substrate etching apparatus 10 may determine optical heating parameters (for example, a pulse interval profile, a scanning speed profile, etc.) such that optical heating for the plurality of points within the single etching region ER is performed at different intensities, respectively. Accordingly, the substrate etching apparatus 10 may perform etching processes at different etch rates for the respective points within the etching region ER.

FIG. 5 is a plan view for describing a method of scanning the etching region ER with a beam spot bs, according to one or more embodiments.

Referring to FIG. 5, the beam spot bs may be moved along a scanning path sp within the etching region ER. The scanning path sp may include a plurality of scan lines (for example, first to sixth scan lines sl1, sl2, sl3, sl4, sl5, and sl6).

Each of the plurality of scan lines may extend in the first horizontal direction, and two adjacent scan lines among the plurality of scan lines may be spaced apart from each other by a scanning interval in the second horizontal direction. For example, the first scan line sl1 and the second scan line sl2 may be spaced apart from each other by a first scanning interval si-a, the second scan line sl2 and the third scan line sl3 may be spaced apart from each other by a second scanning interval si-b, the third scan line sl3 and the fourth scan line sl4 may be spaced apart from each other by a third scanning interval si-c, the fourth scan line sl4 and the fifth scan line sl5 may be spaced apart from each other by a fourth scanning interval si-d, and the fifth scan line sl5 and the sixth scan line sl6 may be spaced apart from each other by a fifth scanning interval si-e. In one or more embodiments, the first to fifth scanning intervals si-a, si-b, si-c, si-d, and si-e may be equal to each other.

In one or more embodiments, the first to fifth scanning intervals si-a, si-b, si-c, si-d, and si-e may be different from each other. For example, strong optical heating may be required for a region between the first scan line sl1 and the second scan line sl2, whereas weak optical heating may be required for a region between the third scan line sl3 and the fourth scan line sl4. In this case, the substrate etching apparatus 10 may determine the first scanning interval si-a to be relatively smaller than the third scanning interval si-c. Accordingly, for the region between the first scan line sl1 and the second scan line sl2, the substrate etching apparatus 10 may perform optical heating by scanning the beam spot bs in an overlapping manner. In detail, during a first scanning cycle in which the beam spot bs moves along the first scan line sl1, first optical heating is performed on the region between the first scan line sl1 and the second scan line sl2, and during a second scanning cycle in which the beam spot bs moves along the second scan line sl2, second optical heating is performed on the region between the first scan line sl1 and the second scan line sl2, such that for the region between the first scan line sl1 and the second scan line sl2, the optical heating may be performed twice in total in an overlapping manner. In contrast, as the substrate etching apparatus 10 determines the third scanning interval si-c to be relatively large, overlapping optical heating may not be performed on a region between the third scan line sl3 and the fourth scan line sl4, and a region where overlapping optical heating is performed may be very small.

As described above, the substrate etching apparatus 10 may determine target optical heating intensities for the respective points within the etching region ER, based on the target etch depth distribution of the etching region ER, and identify scanning intervals respectively corresponding to the determined target optical heating intensities. Accordingly, the substrate etching apparatus 10 may perform optical heating by moving the beam spot bs either in an overlapping manner or independently, by varying the scanning intervals between the plurality of scan lines.

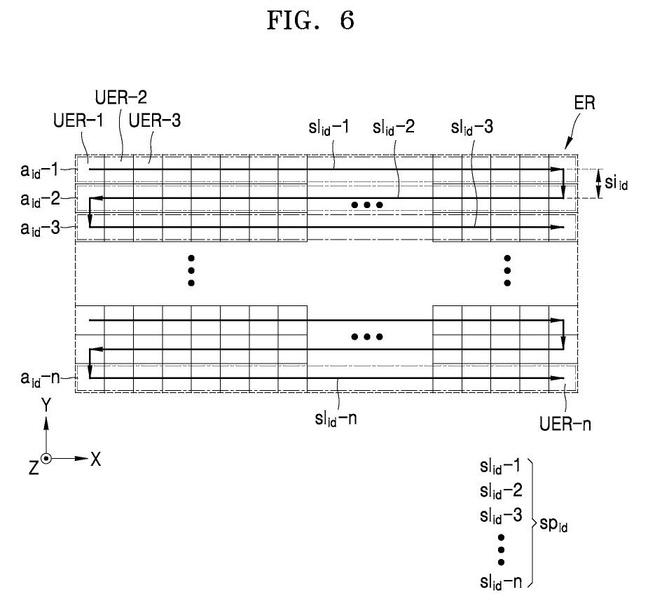

FIG. 6 is a plan view for describing an independent scanning path sp_{id}within the etching region ER, according to one or more embodiments. Referring to FIG. 6, the independent scanning path sp_{id} within the etching region ER may include a plurality of independent scan lines (for example, first to n^{th} scan lines sl_{id}-1, sl_{id}-2, sl_{id}-3, …, and sl_{id}-n). An interval in the second horizontal direction between two adjacent independent scan lines (for example, the first independent scan line sl_{id}-1 and the second independent scan line sl_{id}-2) among the plurality of independent scan lines may be an independent scanning interval si_{id}.

A plurality of independent beam scanning regions (for example, first to n^{th} independent beam scanning regions a_{id}-1, a_{id}-2, a_{id}-3, …, and a_{id}-n) may respectively correspond to the plurality of independent scan lines. For example, the first independent beam scanning region a_{id}-1 may be a scanning region of the beam spot bs along the first independent scan line sl_{id}-1, and the second independent beam scanning region a_{id}-2 may be a scanning region of the beam spot bs along the second independent scan line sl_{id}-2.

In one or more embodiments, the substrate etching apparatus 10 may divide the etching region ER into a plurality of unit etching regions (for example, first to n^{th} unit etching regions UER-1, UER-2, UER-3, …, and UER-n) based on the size of the beam spot bs. As shown in FIG. 6, the plurality of unit etching regions may each be implemented as a rectangular region and may not overlap each other. The rectangular region may be a region where optical heating is performed by the beam spot bs. However, the plurality of unit etching regions are not limited to the rectangular regions, and in one or more embodiments, each of the plurality of unit etching regions may have various shapes such as a circular shape, a triangular shape, or a pentagonal shape.

In one or more embodiments, the substrate etching apparatus 10 may identify the width of a single unit etching region in the second horizontal direction as the independent scanning interval si_{id}. In this case, each of the plurality of independent scan lines may be determined as a straight line that connects centers of the plurality of unit etching regions in the first horizontal direction, and the plurality of independent beam scanning regions may not overlap each other. Accordingly, movement of the beam spot bs may not overlap in the second horizontal direction and may be performed independently along each of the plurality of scan lines.

In another embodiment, the substrate etching apparatus 10 may identify a distance that is greater than the width of a unit etching region in the second horizontal direction, as the independent scanning interval si_{id}. In this case, movement of the beam spot bs may be performed independently along each of the plurality of scan lines, and movement of the beam spot bs may be omitted for some regions between the independent scan lines.

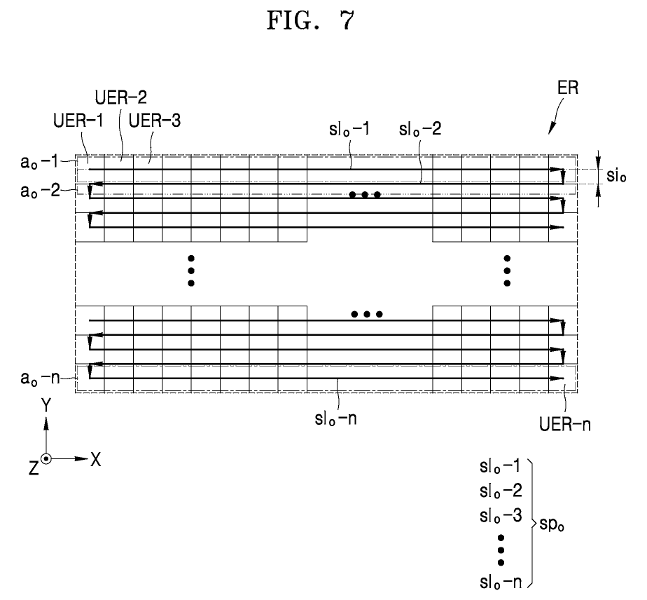

FIG. 7 is a plan view for describing an overlapped scanning path spₒ within the etching region ER, according to one or more embodiments. Referring to FIG. 7, the overlapped scanning path spₒ within the etching region ER may include a plurality of overlapped scan lines (for example, first to n^{th} overlapped scan lines slₒ-1, slₒ-2, …, and slₒ-n). An interval in the second horizontal direction between two adjacent overlapped scan lines (for example, the first overlapped scan line slₒ-1 and the second overlapped scan line slₒ-2) among the plurality of overlapped scan lines may be an overlapped scanning interval siₒ.

A plurality of overlapped beam scanning regions (for example, first to n^{th} overlapped beam scanning regions a₀-1, aₒ-2, …, and a_{O}-n) may respectively correspond to the plurality of overlapped scan lines. For example, the first overlapped beam scanning region aₒ-1 may be a scanning region of the beam spot bs along the first overlapped scan line slₒ-1, and the second overlapped beam scanning region aₒ-2 may be a scanning region of the beam spot bs along the second overlapped scan line slₒ-2. As described above with reference to FIG. 6, the etching region ER may be divided into the plurality of unit etching regions (for example, the first to n^{th} unit etching regions UER-1, UER-2, UER-3, …, and UER-n).

In one or more embodiments, the substrate etching apparatus 10 may identify a distance that is less than the width of a single unit etching region in the second horizontal direction, as the overlapped scanning interval siₒ. In this case, the plurality of overlapped beam scanning regions may partially overlap each other in the second horizontal direction. For example, as shown in FIG. 7, the first overlapped beam scanning region aₒ-1 and the second overlapped beam scanning region aₒ-2 may overlap each other in the second horizontal direction. As the first overlapped beam scanning region aₒ-1 and the second overlapped beam scanning region aₒ-2 overlap each other, optical heating by the beam spot bs may be performed twice on a region where the first overlapped beam scanning region aₒ-1 and the second overlapped beam scanning region aₒ-2 overlap each other.

In one or more embodiments, the substrate etching apparatus 10 may identify, based on a representative value of a target etch depth distribution corresponding to the etching region ER, a scanning interval corresponding to the target etch depth distribution. For example, when the target etch depth distribution of the etching region ER is a first target etch depth distribution, the substrate etching apparatus 10 may identify a first scanning interval corresponding to the first target etch depth distribution, based on a representative value of the first target etch depth distribution. In addition, when the target etch depth distribution of the etching region ER is a second target etch depth distribution, the substrate etching apparatus 10 may identify a second scanning interval corresponding to the second target etch depth distribution, based on a representative value of the second target etch depth distribution. In this regard, when the representative value of the first target etch depth distribution is greater than the representative value of the second target etch depth distribution, the first scanning interval may be determined to be smaller than the second scanning interval. A representative value of a specific distribution may be determined as a median or an average of the distribution. However, the representative value is not limited to the median or the average, and may also be determined as a statistical value such as a mode or a weighted average of the specific distribution.

Accordingly, the substrate etching apparatus 10 may set a smaller scanning interval for an etching region having a relatively large average target etch depth among the plurality of etching regions on the top surface of the target W, such that optical heating by the beam spot bs may be performed in an overlapping manner. In addition, the substrate etching apparatus 10 may set a larger scanning interval for an etching region having a relatively small average target etch depth among the plurality of etching regions, such that optical heating by the beam spot bs may not be performed in an overlapping manner.

In the above description, it has been described that the scanning path within the etching region ER may be implemented as either the independent scanning path sp_{id} or the overlapped scanning path spₒ, but this is merely for convenience of explanation. The scanning path within the etching region ER may include both the independent scanning path sp_{id} and the overlapped scanning path spₒ. For example, the etching region ER may include a first region having a relatively large target etch depth and a second region having a relatively small target etch depth. In this case, the substrate etching apparatus 10 may perform scanning of the first region with the beam spot bs along the overlapped scanning path spₒand may perform scanning of the second region with the beam spot bs along the independent scanning path sp_{id}.

In the above description, it has been described that the substrate etching apparatus 10 may divide the etching region ER into the plurality of unit etching regions based on the size of the beam spot bs, but this is merely an example. The substrate etching apparatus 10 may divide the etching region ER into a plurality of unit etching regions based on a target etch depth distribution of the etching region ER, or may divide the etching region ER into a plurality of unit etching regions based on a reference rectangle (for example, a shape arbitrarily set by a user).

The substrate etching apparatus 10 may identify a scanning speed profile based on a plurality of target etch depths respectively corresponding to the plurality of unit etching regions within the etching region ER.

In one or more embodiments, the substrate etching apparatus 10 may determine a scanning speed profile based on a plurality of target etch depths respectively corresponding to the plurality of unit etching regions. In this regard, the scanning speed profile may include information about a plurality of scanning speeds for the respective unit etching regions.

For example, referring back to FIG. 6, a case is assumed in which a first target etch depth corresponding to the first unit etching region UER-1 is smaller than a second target etch depth corresponding to the second unit etching region UER-2. In this case, the substrate etching apparatus 10 may determine a scanning speed profile such that a first scanning speed corresponding to the first unit etching region UER-1 is set to be greater than a second scanning speed corresponding to the second unit etching region UER-2. In this regard, a scanning speed corresponding to a specific unit etching region may refer to an average speed at which the beam spot bs completely passes through the specific unit etching region. In detail, the first scanning speed may be a value obtained by dividing a distance traveled by the beam spot bs to completely pass through the first unit etching region UER-1 by a time taken for the beam spot bs to completely pass through the first unit etching region UER-1. Although only the first unit etching region UER-1 and the second unit etching region UER-2 have been described as examples, the substrate etching apparatus 10 may perform optical heating corresponding to target etch depths for the respective first to n^{th} unit etching regions UER-1, UER-2, UER-3, …, and UER-n, by setting a scanning speed corresponding to a unit etching region having the largest target etch depth to be the slowest, based on the target etch depths of the first to n^{th} unit etching regions UER-1, UER-2, UER-3, …, and UER-n, and gradually increasing a scanning speed corresponding to a corresponding unit etching region as the target etch depths decrease.

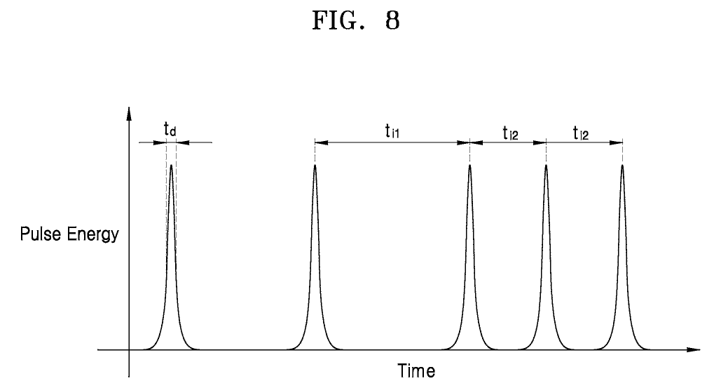

In another embodiment, the substrate etching apparatus 10 may identify a pulse interval profile based on a plurality of target etch depths respectively corresponding to the plurality of unit etching regions. This will be described in detail with reference to FIG. 8.

FIG. 8 is a graph for describing a method of outputting a laser beam from the laser light source 220, according to one or more embodiments. In the graph, the X-axis represents time, and the Y-axis represents pulse energy. The laser light source 220 may output the laser beam La according to a control signal from the controller 500. The graph of FIG. 8 shows five peaks, and each of the five peaks represents pulse energy emitted when the laser light source 220 outputs the laser beam La.

In one or more embodiments, a duration t_{d} of the laser beam La output by the laser light source 220 may range from several femtoseconds (fs) to several hundreds of fs, for example, from one fs to one hundred fs. Because the duration t_{d} of the laser beam La is very short, heat conduction to regions other than the beam spot bs where the laser beam La is focused may be minimized. However, in one or more embodiments, the duration t_{d} of the laser beam La may range from several picoseconds (ps) to several hundreds of ps, and thus, the duration t_{d} of the laser beam La is not limited to the examples described above.

In one or more embodiments, the substrate etching apparatus 10 may identify a pulse interval profile based on a plurality of target etch depths respectively corresponding to the plurality of unit etching regions, and in this regard, the pulse interval profile may include information about a plurality of pulse intervals for the respective unit etching regions.

For example, referring back to FIG. 6, a case may be assumed in which a first target etch depth corresponding to the first unit etching region UER-1 is smaller than a second target etch depth corresponding to the second unit etching region UER-2. In this case, the substrate etching apparatus 10 may determine a pulse interval profile such that a first pulse interval tᵢ₁ corresponding to the first unit etching region UER-1 is set to be greater than a second pulse interval tᵢ₂ corresponding to the second unit etching region UER-2. In this regard, a pulse interval corresponding to a specific unit etching region may be a value obtained by dividing a time taken for the beam spot bs to completely pass through the specific unit etching region by the number of times the laser beam La is output to optically heat the specific unit etching region. In detail, the first pulse interval tᵢ₁ may be a value obtained by dividing a time taken for the beam spot bs to completely pass through the first unit etching region UER-1 by the number of times the laser beam La is output to optically heat the first unit etching region UER-1. Although only the first unit etching region UER-1 and the second unit etching region UER-2 have been described as examples, the substrate etching apparatus 10 may perform optical heating corresponding to target etch depths for the respective first to n^{th} unit etching regions UER-1, UER-2, UER-3, …, and UER-n, by setting a pulse interval corresponding to a unit etching region having the largest target etch depth to be the shortest, based on the target etch depths of the first to n^{th} unit etching regions UER-1, UER-2, UER-3, …, and UER-n, and gradually increasing a pulse interval corresponding to a corresponding unit etching region as the target etch depths decrease. In other words, the substrate etching apparatus 10 may reduce a pulse interval for a unit etching region having a large target etch depth to increase the intensity of optical heating by the laser beam La, and may increase a pulse interval for a unit etching region having a small target etch depth to relatively reduce the intensity of optical heating by the laser beam La.

As described above with reference to FIGS. 6 to 8, the substrate etching apparatus 10 may perform etching processes at different etch rates for the respective unit etching regions by respectively heating the plurality of unit etching regions with different optical heating intensities. In other words, the spatial resolution of an etching process performed by the substrate etching apparatus 10 may be determined by the size of a unit etching region, and the size of the unit etching region may be determined based on the size of the beam spot bs.

FIG. 9 is a conceptual diagram for describing a method of determining the size of the beam spot bs, according to one or more embodiments. Referring to FIG. 9, the size of the beam spot bs may be determined based on a distance between the focusing lens 240 and the target W. The focusing lens 240 may focus the laser beam La toward a focal point fp.

The distance between the target W and the focusing lens 240 may be less than or equal to a focal length f. In one or more embodiments, the distance between the target W and the focusing lens 240 may be a first distance d1. In this case, the size of the beam spot bs may be a first beam size bss-1. In another embodiment, the distance between the target W and the focusing lens 240 may be a second distance d2. In this case, the size of the beam spot bs may be a second beam size bss-2. In this regard, the second beam size bss-2 may be smaller than the first beam size bss-1. In other words, referring back to FIG. 6, the size of a unit etching region is determined based on the size of the beam spot bs, and thus, when the distance between the target W and the focusing lens 240 is the second distance d2, the size of each of the plurality of unit etching regions (for example, the first to n^{th} unit etching regions UER-1, UER-2, UER-3, …, and UER-n) may be smaller than when it is the first distance d1. Accordingly, the etching region ER may include a greater number of unit etching regions, and the spatial resolution of the etching process performed by the substrate etching apparatus 10 may be further improved.

In general, when a variation in a target etch depth distribution corresponding to the etching region ER is large, improved spatial resolution may be required. In this regard, the variation in the target etch depth distribution may be determined based on variations in a plurality of target etch depths respectively corresponding to a plurality of points included in the etching region ER. Referring back to FIG. 4, in general, when the target W includes a large number of protrusions within the etching region ER, the horizontal widths of the protrusions are very small, or the vertical thicknesses of the protrusions are very large, a variation in a target etch depth distribution corresponding to the etching region ER may be large. In contrast, when the target W includes a small number of protrusions within the etching region ER, the horizontal widths of the protrusions are not very small, or the vertical thicknesses of the protrusions are small, a variation in a target etch depth distribution corresponding to the etching region ER may be relatively small. The variation in the target etch depth distribution may be determined by a standard deviation or a coefficient of variation of the distribution. However, the variation is not limited to the standard deviation or the coefficient of variation, and may also be determined by various types of statistical values such as interquartile range and variance.

In one or more embodiments, the substrate etching apparatus 10 may identify the size of the beam spot bs corresponding to the target etch depth distribution, based on the variation in the target etch depth distribution. For example, when the target etch depth distribution of the etching region ER is a first target etch depth distribution, the substrate etching apparatus 10 may identify the first beam size bss-1 as the size of the beam spot bs corresponding to the first target etch depth distribution, based on a variation in the first target etch depth distribution. As another example, when the target etch depth distribution of the etching region ER is a second target etch depth distribution, the substrate etching apparatus 10 may identify the second beam size bss-2 as the size of the beam spot bs corresponding to the second target etch depth distribution, based on a variation in the second target etch depth distribution. In this case, the variation in the first target etch depth distribution may be smaller than the variation in the second target etch depth distribution.

In one or more embodiments, the distance between the target W and the focusing lens 240 may be determined based on driving of the focusing lens 240. As described above with reference to FIG. 1, the focusing lens 240 may be connected to the lens driving device, and the lens driving device may drive the focusing lens 240 in a direction parallel to the optical path bp of the laser beam La. Accordingly, the distance between the target W and the focusing lens 240 may be changed, and the size of the beam spot bs may be determined based on the adjusted distance between the target W and the focusing lens 240. In one or more embodiments, the distance between the target W and the focusing lens 240 may be determined based on driving of the target W. In this case, the stage 300 may be driven in the vertical direction, and as the stage 300 is driven in the vertical direction, the target W may also be driven in the vertical direction. Because the target W is driven in the vertical direction, the distance between the target W and the focusing lens 240 may be changed.

In the above description, only a case is assumed in which the distance between the target W and the focusing lens 240 is less than or equal to the focal length f, but the distance between the target W and the focusing lens 240 may be greater than the focal length f.

In the descriptions of FIGS. 5 to 9, a method of precisely adjusting the intensity of optical heating within the etching region ER based on a scanning interval, a method of precisely adjusting the intensity of optical heating within the etching region ER based on a scanning speed profile, a method of precisely adjusting the intensity of optical heating within the etching region ER based on a pulse interval profile, and a method of precisely adjusting the intensity of optical heating within the etching region ER based on the size of the beam spot bs have each been described separately. However, the methods are described independently only for the convenience of explanation, and the methods may be performed in parallel, or only some of the methods may be selectively combined and performed.

For example, the substrate etching apparatus 10 may first determine, based on a variation in a target etch depth distribution of the etching region ER, the size of the beam spot bs corresponding to the target etch depth distribution, and may divide the etching region ER into a plurality of unit etching regions based on the size of the beam spot bs. Next, the substrate etching apparatus 10 may determine a scanning speed profile based on a plurality of target etch depths respectively corresponding to the plurality of unit etching regions. Next, the substrate etching apparatus 10 may determine a pulse interval profile considering both the plurality of target etch depths respectively corresponding to the plurality of unit etching regions and the scanning speed profile. As another example, the substrate etching apparatus 10 may first determine a pulse interval profile based on a plurality of target etch depths respectively corresponding to the plurality of unit etching regions, and then, may determine a scanning speed profile considering both the plurality of target etch depths and the pulse interval profile.

As another example, the substrate etching apparatus 10 may first determine, based on a variation in a target etch depth distribution of the etching region ER, the size of the beam spot bs corresponding to the target etch depth distribution, and may divide the etching region ER into a plurality of unit etching regions based on the size of the beam spot bs. Next, the substrate etching apparatus 10 may determine a scanning interval based on a representative value of a plurality of target etch depths respectively corresponding to the plurality of unit etching regions. Next, the substrate etching apparatus 10 may determine at least one of a scanning speed profile and a pulse interval profile based on the plurality of target etch depths respectively corresponding to the plurality of unit etching regions. The above description is merely an example of a combination of various methods described with reference to FIGS. 5 to 9, and the various methods may be performed in a different order or in a different combination from those of the above examples.

FIG. 10 is a perspective view of a plasma jet device 100a according to one or more embodiments. Referring to FIG. 10, the plasma jet device 100a may include a jet housing 110a, a first gas inlet 110ha-1, a second gas inlet 110ha-2, a first jet nozzle 110na-1, and a second jet nozzle 110na-2.

In one or more embodiments, the first jet nozzle 110na-1 and the second jet nozzle 110na-2 may eject plasma jets having the same density, toward a bottom portion of the jet housing 110a. To this end, the first jet nozzle 110na-1 and the second jet nozzle 110na-2 may be holes having the same shape, and the first gas inlet 110ha-1 and the second gas inlet 110ha-2 may be holes having the same shape. In addition, gas having the same flow rate may be introduced (or supplied) to each of the first gas inlet 110ha-1 and the second gas inlet 110ha-2. The first jet nozzle 110na-1 and the second jet nozzle 110na-2 may be spaced apart from each other in the first horizontal direction, and the first gas inlet 110ha-1 and the second gas inlet 110ha-2 may also be spaced apart from each other in the first horizontal direction.

In one or more embodiments, as shown in FIG. 10, the first jet nozzle 110na-1 and the second jet nozzle 110na-2 may be rectangular slits having the same width. In addition, the first gas inlet 110ha-1 and the second gas inlet 110ha-2 may be rectangular slits having the same width. In this regard, the widths of the first gas inlet 110ha-1 and the second gas inlet 110ha-2 in the horizontal direction may respectively be greater than the widths of the first jet nozzle 110na-1 and the second jet nozzle 110na-2 in the horizontal direction. When the first jet nozzle 110na-1 and the second jet nozzle 110na-2 are implemented in the form of rectangular slits, the width of each of the first jet nozzle 110na-1 and the second jet nozzle 110na-2 in the first horizontal direction may be greater than the width of each of the first jet nozzle 110na-1 and the second jet nozzle 110na-2 in the second horizontal direction. Accordingly, the plasma jet device 100a may eject the plasma jets extending in the first horizontal direction, toward the top surface of the target W.

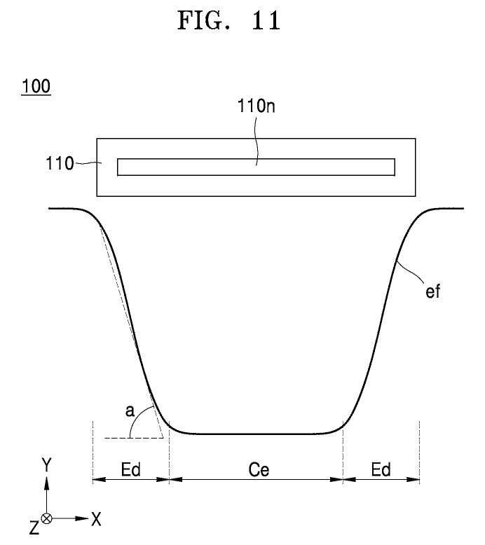

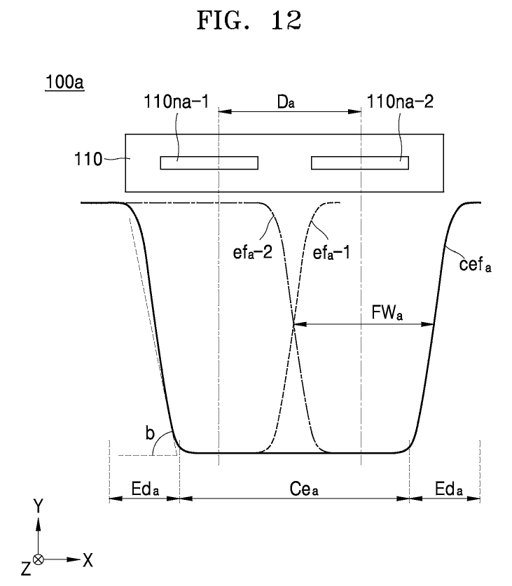

A distance between the first jet nozzle 110na-1 and the second jet nozzle 110na-2 in the first horizontal direction may be determined based on etching profiles of the plasma jets respectively ejected from the first jet nozzle 110na-1 and the second jet nozzle 110na-2. This will be described in detail with reference to FIGS. 11 and 12.

FIG. 11 is a plan view for describing an etching profile of the plasma jet device 100 according to one or more embodiments. FIG. 12 is a plan view for describing an etching profile of the plasma jet device 100a according to one or more embodiments. FIG. 11 shows the bottom surface of the jet housing 110 of the plasma jet device 100 of FIG. 3 and a single etching profile ef, and FIG. 12 shows a bottom surface of the jet housing 110aof the plasma jet device 100aand a combined etching profile cefₐ.

Herein, the term "etching profile" may refer to a distribution that spatially represents the amount and/or configuration of a portion of the target W that is etched (i.e., patterned or removed) by a plasma jet ejected from a jet nozzle. The etching profile may be determined based on a density distribution of the plasma jet ejected from the jet nozzle. For example, the amount by which the target W is etched may be greater in a region where the plasma jet has a higher density, and the amount by which the target W is etched may be smaller in a region where the plasma jet has a lower density. In addition, the density distribution of the plasma jet may be determined based on the shape of the jet nozzle and a flow rate of gas supplied to a gas inlet.

Referring to FIG. 11, the plasma jet device 100 may include the jet nozzle 110n having a single slit shape. In this case, the single etching profile ef may be determined based on a density distribution of a plasma jet ejected from the jet nozzle 110n. As shown in FIG. 11, the single etching profile ef may have the greatest etch depth in a central region Ce and may have a uniform etch depth distribution in the central region Ce. In edge regions Ed, the single etching profile ef may have an etch depth that decreases away from the central region Ce. In one or more embodiments, in the edge regions Ed, the single etching profile ef may have an etch depth that decreases at a slope of a first angle (a).

Referring to FIG. 12, the plasma jet device 100a may include the first jet nozzle 110na-1 and the second jet nozzle 110na-2. In this case, the combined etching profile cefₐ may be determined based on density distributions of plasma jets respectively ejected from the first jet nozzle 110na-1 and the second jet nozzle 110na-2. In detail, the combined etching profile cefₐmay be determined based on a combination of a first etching profile efₐ-1 and a second etching profile efₐ-2. In this regard, the first etching profile efₐ-1 is an etching profile of the plasma jet ejected from the first jet nozzle 110na-1, and the second etching profile efₐ-2 is an etching profile of the plasma jet ejected from the second jet nozzle 110na-2. The first jet nozzle 110na-1 and the second jet nozzle 110na-2 may eject the plasma jets having the same density distribution, and accordingly, the first etching profile efₐ-1 and the second etching profile efₐ-2 may have the same etch depth distribution.

In one or more embodiments, a horizontal distance Dₐ between the first jet nozzle 110na-1 and the second jet nozzle 110na-2 may be less than or equal to a full width at half maximum FWₐ of each of the first etching profile efₐ-1 and the second etching profile efₐ-2 and may be greater than or equal to half of the full width at half maximum FWₐ (FWₐ/2≤Dₐ≤FWₐ). In this regard, the horizontal distance Dₐ may be defined as a distance between a center point of the first jet nozzle 110na-1 and a center point of the second jet nozzle 110na-2. For example, as shown in FIG. 12, the horizontal distance Dₐ may be equal to the full width at half maximum FWₐ. Accordingly, the combined etching profile cefₐ may have a uniform etch depth distribution in a central region Ceₐ and may have the greatest etch depth in the central region Ceₐ. In addition, in edge regions Edₐ, the combined etching profile cefₐmay have an etch depth that decreases at a slope of a second angle (b).

The second angle (b) may be greater than the first angle (a), and a length of the central region Ceₐ of FIG. 12 in the first horizontal direction may be greater than a length of the central region Ce of FIG. 11 in the first horizontal direction. In other words, the plasma jet device 100aincluding the two jet nozzles 110na-1 and 110na-2 may have a uniform etch depth distribution over a larger area than the plasma jet device 100 including only one jet nozzle 110n.

Although the above-detailed embodiments may show the plasma jet device 100 having one rectangular slit-shaped jet nozzle and the plasma jet device 100ahaving two rectangular slit-shaped jet nozzles, the present disclosure is not particularly limited thereto and may also encompass any other suitable configuration, number, and/or shape of jet nozzles. For example, according to one or more embodiments, the respective plasma jet devices 100 and 100a of the present disclosure may include three or more rectangular slit-shaped jet nozzles, and even in this case, a horizontal distance between two adjacent jet nozzles may be less than or equal to a full width at half maximum and may be greater than or equal to half of the full width at half maximum. Unless otherwise indicated, as used herein with regard to any of the respective plasma jet devices, any two jet nozzles are considered “adjacent” to one another so long as no other jet nozzle occupies a space between the two jet nozzles. That is, two jet nozzles of a plasma jet device are considered adjacent if the two jet nozzles are not separated from each other by an intervening jet nozzle.

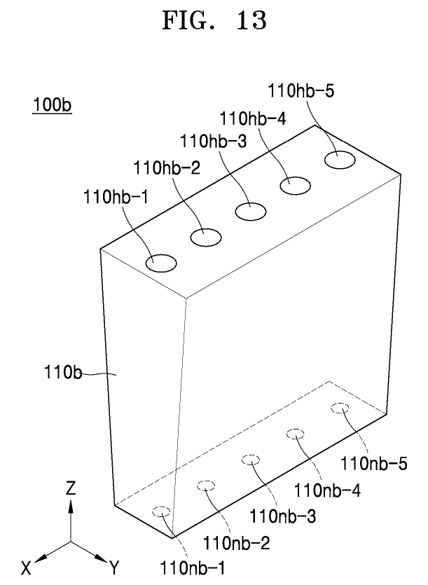

FIG. 13 is a perspective view of a plasma jet device 100b according to one or more embodiments. Referring to FIG. 13, the plasma jet device 100b may include a jet housing 110b, first to fifth gas inlets 110hb-1, 110hb-2, 110hb-3, 110hb-4, and 110hb-5, and first to fifth jet nozzles 110nb-1, 110nb-2, 110nb-3, 110nb-4, and 110nb-5.

In one or more embodiments, the first to fifth jet nozzles 110nb-1, 110nb-2, 110nb-3, 110nb-4, and 110nb-5 may eject plasma jets having the same density, toward a bottom portion of the jet housing 110b. To this end, the first to fifth jet nozzles 110nb-1, 110nb-2, 110nb-3, 110nb-4, and 110nb-5 may be holes having the same shape, and the first to fifth gas inlets 110hb-1, 110hb-2, 110hb-3, 110hb-4, and 110hb-5 may be holes having the same shape. In addition, gas having the same flow rate may be introduced (or supplied) to each of the first to fifth gas inlets 110hb-1, 110hb-2, 110hb-3, 110hb-4, and 110hb-5. The first to fifth jet nozzles 110nb-1, 110nb-2, 110nb-3, 110nb-4, and 110nb-5 may be spaced apart from each other in the first horizontal direction, and the first to fifth gas inlets 110hb-1, 110hb-2, 110hb-3, 110hb-4, and 110hb-5 may be spaced apart from each other in the first horizontal direction.

In one or more embodiments, as shown in FIG. 13, the first to fifth jet nozzles 110nb-1, 110nb-2, 110nb-3, 110nb-4, and 110nb-5 may be circular holes having the same diameter. In addition, the first to fifth gas inlets 110hb-1, 110hb-2, 110hb-3, 110hb-4, and 110hb-5 may be circular holes having the same diameter. As the first to fifth jet nozzles 110nb-1, 110nb-2, 110nb-3, 110nb-4, and 110nb-5 may be sequentially arranged in the first horizontal direction, the plasma jet device 100b may eject the plasma jets extending in the first horizontal direction, toward the top surface of the target W.

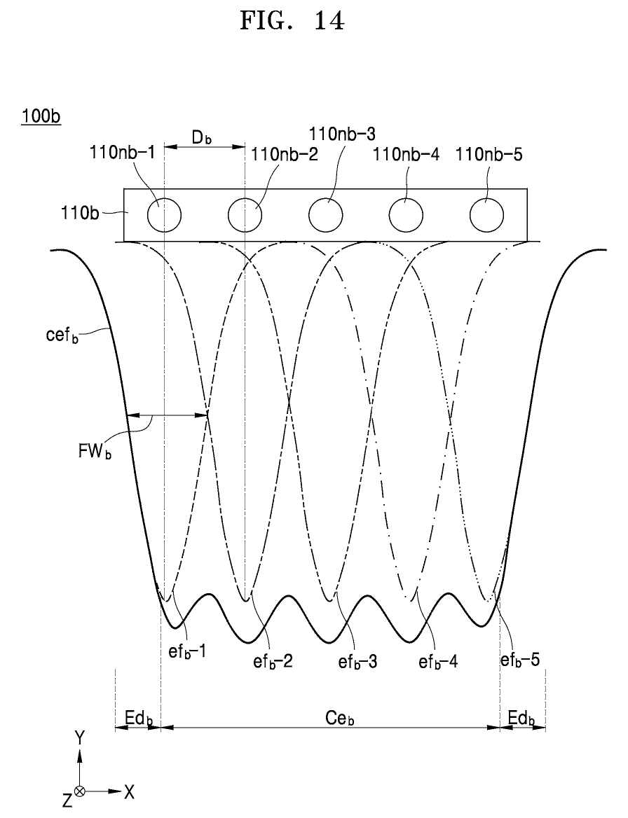

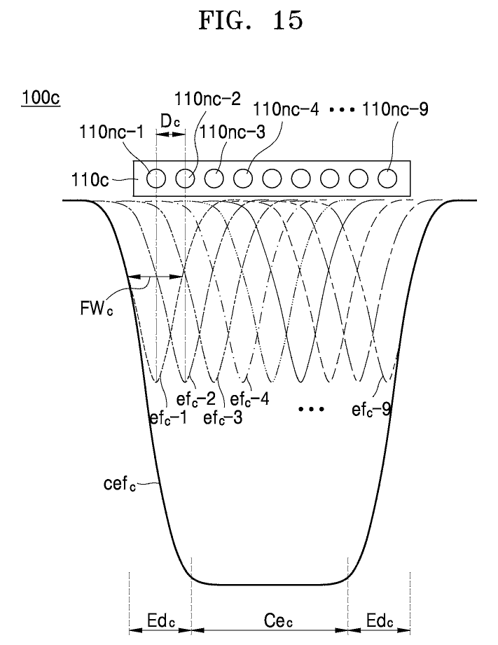

The first to fifth jet nozzles 110nb-1, 110nb-2, 110nb-3, 110nb-4, and 110nb-5 may be spaced apart from each other by the same horizontal distance. A horizontal distance between two adjacent jet nozzles among the first to fifth jet nozzles 110nb-1, 110nb-2, 110nb-3, 110nb-4, and 110nb-5 may be determined based on etching profiles of the plasma jets respectively ejected from the first to fifth jet nozzles 110nb-1, 110nb-2, 110nb-3, 110nb-4, and 110nb-5. This will be described in detail with reference to FIGS. 14 and 15.

FIG. 14 is a plan view for describing an etching profile of the plasma jet device 100b according to one or more embodiments. FIG. 15 is a plan view for describing an etching profile of a plasma jet device 100c according to one or more embodiments. FIG. 14 shows a bottom surface of the jet housing 110b of the plasma jet device 100b of FIG. 13 and a combined etching profile cef_{b}, and FIG. 15 shows a bottom surface of a jet housing 110c of the plasma jet device 100cand a combined etching profile cef_{c}.

Referring to FIG. 14, a first etching profile ef_{b}-1 is an etching profile of the plasma jet ejected from the first jet nozzle 110nb-1, a second etching profile ef_{b}-2 is an etching profile of the plasma jet ejected from the second jet nozzle 110nb-2, a third etching profile ef_{b}-3 is an etching profile of the plasma jet ejected from the third jet nozzle 110nb-3, a fourth etching profile ef_{b}-4 is an etching profile of the plasma jet ejected from the fourth jet nozzle 110nb-4, a fifth etching profile ef_{b}-5 is an etching profile of the plasma jet ejected from the fifth jet nozzle 110nb-5, and the combined etching profile cef_{b} may be determined based on a combination of the first to fifth etching profiles ef_{b}-1, ef_{b}-2, ef_{b}-3, ef_{b}-4, and ef_{b}-5. As described above, the first to fifth jet nozzles 110nb-1, 110nb-2, 110nb-3, 110nb-4, and 110nb-5 eject the plasma jets having the same density distribution, and thus, the first to fifth etching profiles ef_{b}-1, ef_{b}-2, ef_{b}-3, ef_{b}-4, and ef_{b}-5 may have the same distribution.

In one or more embodiments, a horizontal distance D_{b} between two adjacent jet nozzles among the first to fifth jet nozzles 110nb-1, 110nb-2, 110nb-3, 110nb-4, and 110nb-5 may be less than or equal to a full width at half maximum FW_{b} of each of the first to fifth etching profiles ef_{b}-1, ef_{b}-2, ef_{b}-3, ef_{b}-4, and ef_{b}-5 and may be greater than or equal to half of the full width at half maximum FW_{b} (FW_{b}/2≤D_{b}≤FW_{b}). For example, as shown in FIG. 14, the horizontal distance D_{b} between the first jet nozzle 110nb-1 and the second jet nozzle 110nb-2 may be equal to the full width at half maximum FW_{b}. As the horizontal distance D_{b} is set to be substantially equal to the full width at half maximum FW_{b}, the combined etching profile cef_{b} may have a substantially uniform etch depth distribution in a central region Ce_{b}. The combined etching profile cef_{b} may have an oscillatory etch depth distribution in the central region Ce_{b}. The oscillatory etch depth distribution may refer to a distribution in which the etch depth repeatedly increases and decreases in a regular cycle. In the oscillatory etch depth distribution, a variation range of the etch depth may be less than 3 % of the maximum etch depth, and accordingly, the oscillatory etch depth distribution in the central region Ce_{b} may be regarded as a substantially uniform etch depth distribution. In addition, in edge regions Ed_{b}, the combined etching profile cef_{b} may have an etch depth that sharply decreases away from the central region Ce_{b}.

Referring to FIG. 15, the plasma jet device 100cmay include the jet housing 110c and first to ninth jet nozzles 110nc-1, 110nc-2, 110nc-3, 110nc-4, …, and 110nc-9 arranged in the bottom surface of the jet housing 110c. First to ninth etching profiles ef_{c}-1, ef_{c}-2, ef_{c}-3, ef_{c}-4, …, and ef_{c}-9 may respectively be etching profiles of plasma jets respectively ejected from the first to ninth jet nozzles 110nc-1, 110nc-2, 110nc-3, 110nc-4, …, and 110nc-9. For example, the first etching profile ef_{c}-1 may be an etching profile of the plasma jet ejected from the first jet nozzle 110nc-1. The first to ninth jet nozzles 110nc-1, 110nc-2, 110nc-3, 110nc-4, …, and 110nc-9 eject the plasma jets having the same density distribution, and thus, the first to ninth etching profiles ef_{c}-1, ef_{c}-2, ef_{c}-3, ef_{c}-4, …, and ef_{c}-9 may have the same etch depth distribution. In addition, the combined etching profile cef_{c}may be determined based on a combination of the first to ninth etching profiles ef_{c}-1, ef_{c}-2, ef_{c}-3, ef_{c}-4, …, and ef_{c}-9.

In one or more embodiments, a horizontal distance D_{c} between two adjacent jet nozzles among the first to ninth jet nozzles 110nc-1, 110nc-2, 110nc-3, 110nc-4, …, and 110nc-9 may be less than or equal to a full width at half maximum FW_{c} of each of the first to ninth etching profiles ef_{c}-1, ef_{c}-2, ef_{c}-3, ef_{c}-4, …, and ef_{c}-9 and may be greater than or equal to half of the full width at half maximum FW_{c} (FW_{c}/2≤D_{c}≤FW_{c}). For example, as shown in FIG. 15, the horizontal distance D_{c} may be equal to half of the full width at half maximum FW_{c} (D_{c} = FW_{c}/2). As the horizontal distance D_{c} is set to be equal to half of the full width at half maximum FW_{c}, the combined etching profile cef_{c} may have a uniform etch depth distribution in a central region Ce_{c}. In addition, in edge regions Ed_{c}, the combined etching profile cef_{c} may have an etch depth that sharply decreases away from the central region Ce_{c.} Compared to the plasma jet device 100b of FIG. 14, the plasma jet device 100c of FIG. 15 includes a greater number of jet nozzles, and thus, a length of the central region Ce_{c} in the first horizontal direction may be greater than a length of the central region Ce_{b} in the first horizontal direction. In other words, the plasma jets ejected from the plasma jet device 100c may have a uniform density distribution or a uniform etch depth distribution over a larger region than the plasma jets ejected from the plasma jet device 100b.

Although FIG. 14 shows that the plasma jet device 100b may include five jet nozzles, and FIG. 15 shows that the plasma jet device 100c may include nine jet nozzles, this is merely for convenience of explanation, and the present disclosure is not limited thereto. The plasma jet devices 100b and 100caccording to one or more embodiments may include two or more circular hole-shaped jet nozzles, and even in this case, a horizontal distance between two adjacent jet nozzles may be less than or equal to a full width at half maximum and may be greater than or equal to half of the full width at half maximum.

As described above with reference to FIGS. 14 and 15, the plasma jet devices 100band 100cmay eject, toward the target W, plasma jets having a uniform etch depth distribution over a large region, by including a plurality of jet nozzles that are spaced apart from each other by the horizontal distances D_{b} and D_{c}. Accordingly, the substrate etching apparatus 10 may have improved throughput. The substrate etching apparatus 10 may improve throughput by using a plasma jet having a uniform etch depth distribution over a large region, and as described above with reference to FIGS. 4 to 9, the substrate etching apparatus 10 may have improved spatial resolution of an etching process by adjusting at least one parameter of the size of the beam spot bs, a scanning interval, a scanning speed profile, and a pulse interval profile based on a target etch depth distribution.

FIG. 16 is a perspective view of a substrate etching apparatus 10d according to one or more embodiments. FIG. 17 is a plan view for describing an optical heating method for the substrate etching apparatus 10d, according to one or more embodiments.

Referring to FIG. 16, the substrate etching apparatus 10d may include a plasma jet device 100dand a plurality of optical heating modules (for example, first to fourth optical heating modules 200-1, 200-2, 200-3, and 200-4).

The plasma jet device 100dmay include a jet housing 110dand a plurality of gas inlets (for example, first to n^{th} gas inlets 110hd-1, 110hd-2, 110hd-3, …, and 110hd-n) arranged in a top surface of the jet housing 110d. In addition, the plasma jet device 100dmay include a plurality of jet nozzles arranged in a bottom surface of the jet housing 110d, and the plurality of jet nozzles may be arranged at positions respectively corresponding to the plurality of gas inlets. For example, horizontal coordinates of centers of the plurality of jet nozzles may respectively be substantially identical to horizontal coordinates of centers of the plurality of gas inlets.

In one or more embodiments, the plurality of jet nozzles may be circular holes having the same diameter. In addition, the plurality of gas inlets may be circular holes having the same diameter. The diameter of each of the plurality of jet nozzles may be smaller than the diameter of each of the plurality of gas inlets. The plurality of jet nozzles may respectively eject plasma jets toward the etching region ER of the target W. For example, the plurality of jet nozzles may respectively eject plasma jets having the same density distribution, toward the etching region ER.

In one or more embodiments, a horizontal distance between two adjacent jet nozzles among the plurality of jet nozzles may be less than or equal to a full width at half maximum of an etching profile of a plasma jet ejected from a single jet nozzle and may be greater than or equal to half of the full width at half maximum. The horizontal distance between the two adjacent jet nozzles and the full width at half maximum of the etching profile have been described above with reference to FIGS. 10 to 15, and thus, descriptions thereof are omitted.

The plasma jet device 100d may eject plasma jets having a uniform distribution over a large region, by including a large number of jet nozzles. Accordingly, in one or more embodiments, as shown in FIG. 16, a portion of the etching region ER may extend to a region outside the target W.

The first optical heating module 200-1 may include a first laser light source 220-1, a first scanning mirror 230-1, and a first focusing lens 240-1, the second optical heating module 200-2 may include a second laser light source 220-2, a second scanning mirror 230-2, and a second focusing lens 240-2, the third optical heating module 200-3 may include a third laser light source 220-3, a third scanning mirror 230-3, and a third focusing lens 240-3, and the fourth optical heating module 200-4 may include a fourth laser light source 220-4, a fourth scanning mirror 230-4, and a fourth focusing lens 240-4. The etching region ER may include first to fourth sub-etching regions SER-1, SER-2, SER-3, and SER-4, and the first to fourth optical heating modules 200-1, 200-2, 200-3, and 200-4 may optically heat the first to fourth sub-etching regions SER-1, SER-2, SER-3, and SER-4 via first to fourth laser beams La-1, La-2, La-3, and La-4, respectively.

In detail, the first to fourth optical heating modules 200-1, 200-2, 200-3, and 200-4 may optically heat the first to fourth sub-etching regions SER-1, SER-2, SER-3, and SER-4, respectively, based on a method that is identical or similar to beam spot scanning-based optical heating methods described with reference to FIGS. 5 to 7.

By including the plurality of optical heating modules (for example, the first to fourth optical heating modules 200-1, 200-2, 200-3, and 200-4) respectively corresponding to a plurality of sub-etching regions (for example, the first to fourth sub-etching regions SER-1, SER-2, SER-3, and SER-4), the substrate etching apparatus 10dmay perform efficient optical heating over the entire etching region ER, even when the size of the etching region ER is significantly increased. For example, the etching region ER may be larger than a scannable region of a single scanning mirror (for example, the first scanning mirror 230-1). In this case, optical heating over the entire etching region ER may not be performed using only a single optical heating module (for example, the first optical heating module 200-1). To address this issue, the substrate etching apparatus 10d may divide the etching region ER into a plurality of sub-etching regions and perform optical heating on the plurality of sub-etching regions respectively via the plurality of optical heating modules.

Although FIG. 16 shows that the substrate etching apparatus 10d may include four optical heating modules respectively corresponding to four sub-etching regions, this is merely an example for convenience of explanation. The substrate etching apparatus 10d according to one or more embodiments may include two or three optical heating modules or may include five or more optical heating modules.

Referring to FIG. 17, first to fourth beam spots bs1, bs2, bs3, and bs4 may move along first to fourth scanning paths sp1, sp2, sp3, and sp4, respectively.

The first to fourth beam spots bs1, bs2, bs3, and bs4 may respectively refer to regions where the first to fourth laser beams La-1, La-2, La-3, and La-4 are focused. The first to fourth laser beams La-1, La-2, La-3, and La-4 may respectively be output from the first to fourth laser light sources 220-1, 220-2, 220-3, and 220-4, and the first to fourth laser beams La-1, La-2, La-3, and La-4 may respectively be focused by the first to fourth focusing lenses 240-1, 240-2, 240-3, and 240-4. In addition, the movement of the first to fourth beam spots bs1, bs2, bs3, and bs4 may respectively be performed based on rotational driving of the first to fourth scanning mirrors 230-1, 230-2, 230-3, and 230-4.

The first to fourth scanning paths sp1, sp2, sp3, and sp4 may respectively be scanning paths within the first to fourth sub-etching regions SER-1, SER-2, SER-3, and SER-4. For example, the first scanning path sp1 may be the scanning path within the first sub-etching region SER-1, and the second scanning path sp2 may be the scanning path within the second sub-etching region SER-2.

In one or more embodiments, the first to fourth scanning paths sp1, sp2, sp3, and sp4 may respectively be determined based on target etch depth distributions of the first to fourth sub-etching regions SER-1, SER-2, SER-3, and SER-4. Accordingly, the first to fourth scanning paths sp1, sp2, sp3, and sp4 may respectively be implemented as different types of paths.

First to fourth scanning intervals si1, si2, si3, and si4 may respectively be determined based on representative values of the target etch depth distributions of the first to fourth sub-etching regions SER-1, SER-2, SER-3, and SER-4. Accordingly, the first to fourth scanning intervals si1, si2, si3, and si4 may not be substantially identical. In this regard, the first to fourth scanning intervals si1, si2, si3, and si4 may respectively correspond to the first to fourth scanning paths sp1, sp2, sp3, and sp4. For example, the first scanning path sp1 may include a plurality of first scan lines extending in the first horizontal direction, and the plurality of first scan lines may be spaced apart from each other by the first scanning interval si1 in the second horizontal direction.

For example, the representative value of the target etch depth distribution of the first sub-etching region SER-1 may be greater than the representative value of the target etch depth distribution of the second sub-etching region SER-2. In this case, the first scanning interval si1 may be smaller than the second scanning interval si2. As the first scanning interval si1 is set to be smaller than the second scanning interval si2, optical heating based on the scanning of the first sub-etching region SER-1 with the first beam spot bs1 may be performed in a more overlapping manner than optical heating based on the scanning of the second sub-etching region SER-2 with the second beam spot bs2.

As shown in FIG. 17, the first scanning interval si1 and the third scanning interval si3 may be substantially identical, and the second scanning interval si2 and the fourth scanning interval si4 may be substantially identical, but the first scanning interval si1 and the second scanning interval si2 may be different from each other. The above example is merely for convenience of explanation, and the first to fourth scanning intervals si1, si2, si3, and si4 may be implemented as the same interval, or at least some of the first to fourth scanning intervals si1, si2, si3, and si4 may be substantially identical, whereas the others may be different from each other.

As shown in FIG. 17, a portion of the first sub-etching region SER-1 and a portion of the fourth sub-etching region SER-4 may be arranged in a region outside the target W. Accordingly, the substrate etching apparatus 10dmay limit and determine the first scanning path sp1 and the fourth scanning path sp4 to prevent the movement of the first beam spot bs1 and the movement of the fourth beam spot bs4 from extending to a region outside the target W. For example, the first scanning path sp1 may include a plurality of first scan lines extending in the first horizontal direction and having different horizontal lengths. The plurality of first scan lines may not extend beyond a boundary of the target W, and a start point or end point of each of the plurality of first scan lines may be in contact with the boundary of the target W. In this regard, the boundary of the target W may refer to a line separating an internal region of the target W from a region outside the target W. For example, when the internal region of the target W is a circle, the boundary of the target W may be the circumference of the circle.

In one or more embodiments, the sizes of the first to fourth beam spots bs1, bs2, bs3, and bs4 may respectively be determined based on variations in target etch depth distributions of the first to fourth sub-etching regions SER-1, SER-2, SER-3, and SER-4. Accordingly, the sizes of the first to fourth beam spots bs1, bs2, bs3, and bs4 may not be substantially identical. A method of determining the size of a beam spot based on a variation in a target etch depth distribution is as described above with reference to FIG. 9, and thus, a detailed description thereof is omitted. As a simple example, a variation in the target etch depth distribution of the third sub-etching region SER-3 may be the largest, and a variation in the target etch depth distribution of the second sub-etching region SER-2 may be the smallest. Accordingly, the third beam spot bs3 may have the smallest size, and the second beam spot bs2 may have the largest size. The sizes of the first to fourth beam spots bs1, bs2, bs3, and bs4 may respectively be determined based on relative positions of the first to fourth focusing lenses 240-1, 240-2, 240-3, and 240-4 with respect to the target W.

In one or more embodiments, scanning speed profiles of the first to fourth beam spots bs1, bs2, bs3, and bs4 may respectively be determined based on target etch depth distributions of the first to fourth sub-etching regions SER-1, SER-2, SER-3, and SER-4. A method, performed by the substrate etching apparatus 10d, of determining a scanning speed profile based on a target etch depth distribution is as described above with reference to FIGS. 4, 6 and 7, and thus, a detailed description thereof is omitted.

In one or more embodiments, pulse interval profiles of the first to fourth laser beams La-1, La-2, La-3, and La-4 may respectively be determined based on target etch depth distributions of the first to fourth sub-etching regions SER-1, SER-2, SER-3, and SER-4. A method, performed by the substrate etching apparatus 10d, of determining a pulse interval profile based on a target etch depth distribution is as described above with reference to FIG. 8, and thus, a detailed description thereof is omitted.

The substrate etching apparatus 10d according to one or more embodiments may include: the plasma jet device 100dthat ejects plasma jets having a uniform etching profile over a large region; and the plurality of optical heating modules, and thus, may rapidly perform an etching process on the entire region of the top surface of the target W. In addition, the substrate etching apparatus 10dmay have improved spatial resolution of an etching process by including the plurality of optical heating modules that respectively perform optical heating on the plurality of sub-etching regions.

According to an aspect of the disclosure, there is provided a substrate etching method for a substrate etching apparatus, the method including dividing a top surface of a target into a plurality of etching regions based on ejection widths of plasma jets ejected by a plasma jet device, identifying a plurality of target etch depth distributions respectively corresponding to the plurality of etching regions, identifying a plurality of optical heating parameter sets respectively corresponding to the plurality of target etch depth distributions, and performing a local etching process on the plurality of etching regions based on the respective optical heating parameter sets, via the plasma jet device and an optical heating module, wherein the performing of the local etching process includes ejecting the plasma jets toward the plurality of etching regions, respectively, via the plasma jet device, and moving, via the optical heating module, a beam spot of a laser beam along a scanning path within each of the plurality of etching regions based on the respective optical heating parameter sets, and each of the plurality of optical heating parameter sets includes a size of the beam spot, a scanning interval of the scanning path, a scanning speed profile, and a pulse interval profile of the laser beam.

In one or more embodiments, the identifying of the plurality of optical heating parameter sets respectively corresponding to the plurality of target etch depth distributions may include identifying variations in the respective target etch depth distributions, and identifying the sizes of the beam spots respectively corresponding to the plurality of target etch depth distributions, based on the variations in the respective target etch depth distributions.

In one or more embodiments, the plurality of target etch depth distributions may include a first target etch depth distribution and a second target etch depth distribution, the identifying of the sizes of the beam spots respectively corresponding to the plurality of target etch depth distributions may include determining a first beam size corresponding to the first target etch depth distribution to be greater than a second beam size corresponding to the second target etch depth distribution, and a variation in the first target etch depth distribution may be smaller than a variation in the second target etch depth distribution.

In one or more embodiments, the identifying of the plurality of optical heating parameter sets respectively corresponding to the plurality of target etch depth distributions may include identifying representative values of the respective target etch depth distributions and identifying the scanning intervals respectively corresponding to the plurality of target etch depth distributions, based on the representative values of the respective target etch depth distributions, the scanning path may include a plurality of scan lines extending in a first horizontal direction, the scanning interval may be a distance between two adjacent scan lines in a second horizontal direction among the plurality of scan lines, and the first horizontal direction and the second horizontal direction may be perpendicular to each other.

In one or more embodiments, the plurality of target etch depth distributions may include a first target etch depth distribution and a second target etch depth distribution, the identifying of the scanning intervals respectively corresponding to the plurality of target etch depth distributions may include determining a first scanning interval corresponding to the first target etch depth distribution to be smaller than a second scanning interval corresponding to the second target etch depth distribution, and a representative value of the first target etch depth distribution may be greater than a representative value of the second target etch depth distribution.

In one or more embodiments, the identifying of the plurality of optical heating parameter sets respectively corresponding to the plurality of target etch depth distributions may include dividing each of the plurality of etching regions into a plurality of unit etching regions and identifying the scanning speed profile based on a plurality of target etch depths respectively corresponding to the plurality of unit etching regions, and the scanning speed profile may include information about a plurality of scanning speeds respectively corresponding to the plurality of unit etching regions.

In one or more embodiments, the plurality of unit etching regions may include a first unit etching region and a second unit etching region, the identifying of the scanning speed profile may include determining a first scanning speed corresponding to the first unit etching region to be greater than a second scanning speed corresponding to the second unit etching region, and a first target etch depth of the first unit etching region may be smaller than a second target etch depth of the second unit etching region.

In one or more embodiments, the identifying of the plurality of optical heating parameter sets respectively corresponding to the plurality of target etch depth distributions may include dividing each of the plurality of etching regions into a plurality of unit etching regions and identifying the pulse interval profile based on a plurality of target etch depths respectively corresponding to the plurality of unit etching regions, and the pulse interval profile may include information about a plurality of pulse intervals respectively corresponding to the plurality of unit etching regions.

In one or more embodiments, the plurality of unit etching regions may include a first unit etching region and a second unit etching region, the identifying of the pulse interval profile may include determining a first pulse interval corresponding to the first unit etching region to be greater than a second pulse interval corresponding to the second unit etching region, and a first target etch depth of the first unit etching region may be smaller than a second target etch depth of the second unit etching region.

In one or more embodiments, the performing of the local etching process may include outputting the laser beam with a duration ranging from about one or several femtoseconds (fs) to about one hundred or several hundred fs.

While the present disclosure has been particularly shown and described with reference to embodiments thereof, it will be understood that various changes in form and details may be made therein without departing from the spirit and scope of the following claims.

What is claimed is:

1. A substrate etching apparatus comprising:
a plasma jet device configured to eject a plasma jet toward an etching region, the etching region comprising a portion of a top surface of a target; and
an optical heating module configured to radiate a laser beam to the etching region, the optical heating module comprising:
a laser light source configured to output the laser beam;
a focusing lens configured to focus the laser beam onto a beam spot on the top surface of the target; and
a scanning mirror between the laser light source and the focusing lens along an optical path of the laser beam, and configured to move the beam spot along a scanning path within the etching region.

2. The substrate etching apparatus of claim 1, wherein the plasma jet device comprises:
a jet housing; and
a plurality of jet nozzles at a bottom surface of the jet housing and respectively configured to eject plasma jets toward the target,
wherein the plasma jets are respectively configured to etch etching profiles in the target, and
wherein a distance between two adjacent jet nozzles of the plurality of jet nozzles is less than or equal to a full width at half maximum (FWHM) of an etching profile of the etching profiles and is greater than or equal to half of the FWHM.

3. The substrate etching apparatus of claim 2, wherein the plurality of jet nozzles respectively comprise rectangular slits having substantially identical respective widths.

4. The substrate etching apparatus of claim 2, wherein the plurality of jet nozzles respectively comprise circular holes having a same diameter.

5. The substrate etching apparatus of claim 1, wherein the optical heating module further comprises:
a lens driving device configured to:
adjust a size of the beam spot by adjusting a position of the focusing lens in a direction parallel to the optical path of the laser beam.

6. The substrate etching apparatus of claim 5, wherein the etching region comprises a plurality of points within the etching region, and
wherein the lens driving device is further configured to adjust the size of the beam spot based on a variation in a plurality of target etch depths respectively corresponding to the plurality of points.

7. The substrate etching apparatus of claim 1, wherein the scanning path comprises an independent scanning path,
wherein the independent scanning path comprises a plurality of scan lines extending in a horizontal direction, and
wherein a plurality of beam scanning regions respectively corresponding to the plurality of scan lines do not overlap each other.

8. The substrate etching apparatus of claim 1, wherein the scanning path comprises an overlapped scanning path,
wherein the overlapped scanning path comprises a plurality of scan lines extending in a first horizontal direction,
wherein a plurality of beam scanning regions respectively corresponding to the plurality of scan lines overlap each other in a second horizontal direction, and
wherein the first horizontal direction and the second horizontal direction are perpendicular to each other.

9. The substrate etching apparatus of claim 1, further comprising a stage configured to support the target and drive the target in a horizontal direction,
wherein the stage comprises a cooling path therein, the cooling path being configured to lower a temperature of the target.

10. The substrate etching apparatus of claim 1, wherein the laser light source is further configured to output the laser beam for a duration of about one femtosecond (fs) to about one hundred fs.

11. A substrate etching apparatus comprising:
a plasma jet device configured to eject a plasma jet toward a top surface of a target;
a laser light source configured to output a laser beam;
a focusing lens configured to focus the laser beam onto a beam spot on a portion of the top surface of the target;
a scanning mirror between the laser light source and the focusing lens along an optical path of the laser beam;
a stage configured to support the target and drive the target in a horizontal direction; and
a controller configured to control the stage and the scanning mirror,
wherein the controller is configured to:
identify an etching region on the top surface of the target based on information about the stage driving the target, and
control the scanning mirror to move the beam spot along a scanning path within the etching region.

12. The substrate etching apparatus of claim 11, further comprising a lens driving device configured to move the focusing lens in a direction parallel to the optical path of the laser beam,
wherein the etching region comprises a plurality of points,
wherein the controller is further configured to adjust, based on a variation in a plurality of target etch depths respectively corresponding to the plurality of points, a size of the beam spot by controlling the lens driving device to move the focusing lens.

13. The substrate etching apparatus of claim 11, wherein the etching region comprises a plurality of unit etching regions, and
wherein the controller is further configured to control the scanning mirror to move the beam spot according to a scanning speed profile based on a plurality of target etch depths respectively corresponding to the plurality of unit etching regions.

14. The substrate etching apparatus of claim 13, wherein the plurality of unit etching regions comprises a first unit etching region and a second unit etching region,
wherein the scanning speed profile comprises a first scanning speed corresponding to the first unit etching region and a second scanning speed corresponding to the second unit etching region,
wherein the first scanning speed is greater than the second scanning speed, and
wherein a first target etch depth corresponding to the first unit etching region is smaller than a second target etch depth corresponding to the second unit etching region.

15. The substrate etching apparatus of claim 11, wherein the scanning path comprises at least one of an independent scanning path or an overlapped scanning path,
wherein the independent scanning path comprises:
a plurality of independent scan lines extending in a first horizontal direction; and
a plurality of beam scanning regions respectively corresponding to the plurality of independent scan lines without overlapping each other;
wherein the overlapped scanning path comprises:
a plurality of overlapped scan lines extending in the first horizontal direction; and
a plurality of beam scanning regions overlapping each other in a second horizontal direction and respectively corresponding to the plurality of overlapped scan lines, and
wherein the first horizontal direction and the second horizontal direction are perpendicular to each other.

16. The substrate etching apparatus of claim 11, wherein the etching region comprises a plurality of unit etching regions, and
wherein the controller is further configured to control the laser light source to output the laser beam according to a pulse interval profile based on a plurality of target etch depths respectively corresponding to the plurality of unit etching regions.

17. The substrate etching apparatus of claim 16, wherein the plurality of unit etching regions comprises a first unit etching region and a second unit etching region,
wherein the pulse interval profile comprises a first pulse interval corresponding to the first unit etching region and a second pulse interval corresponding to the second unit etching region,
wherein the first pulse interval is greater than the second pulse interval, and
wherein a first target etch depth corresponding to the first unit etching region is smaller than a second target etch depth corresponding to the second unit etching region.

18. The substrate etching apparatus of claim 11, wherein the controller is further configured to control the laser light source to output the laser beam for a duration ranging from about one femtosecond (fs) to about one hundred fs.

19. A substrate etching apparatus comprising:
a stage configured to support a target and drive the target in a horizontal direction;
a plasma jet device comprising a plurality of jet nozzles respectively configured to eject plasma jets toward an etching region of the target; and
a plurality of optical heating modules respectively configured to output a plurality of laser beams respectively corresponding to a plurality of sub-etching regions in the etching region,
wherein each of the plurality of optical heating modules comprise:
a laser light source configured to output a laser beam of the plurality of laser beams;
a focusing lens configured to focus the laser beam onto a beam spot on a top surface of the target; and
a scanning mirror between the laser light source and the focusing lens along an optical path of the laser beam, and
wherein the scanning mirrors of the plurality of optical heating modules are respectively configured to move the beam spots along a plurality of scanning paths respectively corresponding to the plurality of sub-etching regions.

20. The substrate etching apparatus of claim 19, further comprising a controller,
wherein each of the plurality of sub-etching regions comprises a plurality of unit etching regions, and
wherein the controller is configured to determine a scanning speed profile of the beam spot based on a plurality of target etch depths respectively corresponding to the plurality of unit etching regions.
